(19) United States
(12) Patent Application Publication
(10) Pub. No.: US 2026/0371840 A1
(43) Pub. Date: Nov. 19, 2026

(54) LIGHT EMITTING DEVICE AND ELECTRONIC DEVICE

(71) Applicant: SONY SEMICONDUCTOR SOLUTIONS CORPORATION, KANAGAWA (JP)

(72) Inventors: MASAYA OGURA, KANAGAWA (JP); TOMOAKI SAWABE, KANAGAWA (JP); TOSHIYA YONEHARA, KANAGAWA (JP); NAOYA KASAHARA, KANAGAWA (JP); KENICHI AOYAGI, KANAGAWA (JP); MASATAKA SUGIYASU, KANAGAWA (JP)

(21) Appl. No.: 19/135,553

(22) PCT Filed: Dec. 12, 2023
(86) PCT No.: PCT/JP2023/044342

§ 371 Date: Jun. 4, 2025

(30) Foreign Application Priority Data
Dec. 12, 2022 (JP) 2022-197937

(51) Int. Cl. H10K 50/858; H10K 50/844; H10K 59/12; H10K 59/131; H10K 59/38

(52) U.S. Cl. CPC H10K 50/858; H10K 50/844; H10K 59/1201; H10K 59/1315; H10K 59/38

(57) ABSTRACT

Provided is a light emitting device including a plurality of light emitting elements arrayed on a substrate. Each of the light emitting elements includes: a first electrode provided on the substrate; a light emitting layer stacked on the first electrode to emit light; a second electrode stacked on the light emitting layer to transmit the light from the light emitting layer; and a first protective film stacked on the second electrode to transmit the light from the light emitting layer. The first protective films of the adjacent light emitting elements are provided to be continuous with each other. The first protective film has a first trench that partitions the adjacent light emitting elements. A low refractive index film having a refractive index lower than a refractive index of the first protective film is embedded in the first trench.

### FIELD

The present disclosure relates to a light emitting device and an electronic device.

### BACKGROUND

In recent years, display devices (light emitting devices) using an organic electroluminescence (EL) element as a light emitting element are under active development. The display device includes, for example, a plurality of pixels including a lower electrode, a light emitting layer stacked on the lower electrode, and an upper electrode stacked on the light emitting layer. When a predetermined voltage is supplied to the lower electrode and the upper electrode, the light emitting layer sandwiched between the lower electrode and the upper electrode emits light. For example, an example of such a display device is a display device in the following Patent Literature.

### CITATION LIST

### Patent Literature

Patent Literature 1: JP 2014-96346 A

### SUMMARY

### Technical Problem

However, regarding the display device (light emitting device) having a plurality of pixels as described above, there have been no deeper examinations made on improvement in extraction efficiency of light from the pixels.

In view of this, the present disclosure proposes a light emitting device and an electronic device capable of improving the light extraction efficiency.

### Solution to Problem

According to the present disclosure, there is provided a light emitting device including a plurality of light emitting elements arrayed on a substrate. In the light emitting device, each of the light emitting elements includes: a first electrode provided on the substrate; a light emitting layer stacked on the first electrode to emit light; a second electrode stacked on the light emitting layer to transmit the light from the light emitting layer; and a first protective film stacked on the second electrode to transmit the light from the light emitting layer, the first protective films of the adjacent light emitting elements are provided to be continuous with each other, the first protective film has a first trench that partitions the adjacent light emitting elements, and a low refractive index film having a refractive index lower than a refractive index of the first protective film is embedded in the first trench.

Furthermore, according to the present disclosure, there is provided an electronic device equipped with a light emitting device, the light emitting device includes a plurality of light emitting elements arrayed on a substrate. In the light emitting device, each of the light emitting elements includes: a first electrode provided on the substrate; a light emitting layer stacked on the first electrode to emit light; a second electrode stacked on the light emitting layer to transmit the light from the light emitting layer; and a first protective film stacked on the second electrode to transmit the light from the light emitting layer, the first protective films of the adjacent light emitting elements are provided to be continuous with each other, the first protective film has a first trench that partitions the adjacent light emitting elements, and a low refractive index film having a refractive index lower than a refractive index of the first protective film is embedded in the first trench.

### BRIEF DESCRIPTION OF DRAWINGS

FIG. 1 is a schematic diagram illustrating an example of an overall configuration of a light emitting device according to an embodiment of the present disclosure.

FIG. 2 is a schematic circuit diagram for illustrating a connection relationship in a subpixel of an mth row and an nth column.

FIG. 3 is a cross-sectional view for illustrating an example of a configuration of a pixel according to a comparative example.

FIG. 4 is a cross-sectional view for illustrating an example of a configuration of a pixel according to a first embodiment of the present disclosure.

FIG. 5 is a cross-sectional view for illustrating an example of a configuration of a pixel according to a second embodiment of the present disclosure.

FIG. 6 is a cross-sectional view (part 1) for illustrating an example of a configuration of a pixel according to a modification of the second embodiment of the present disclosure.

FIG. 7 is a cross-sectional view (part 2) for illustrating an example of a configuration of a pixel according to a modification of the second embodiment of the present disclosure.

FIG. 8 is a cross-sectional view (part 3) for illustrating an example of a configuration of a pixel according to a modification of the second embodiment of the present disclosure.

FIG. 9 is a cross-sectional view (part 4) for illustrating an example of a configuration of a pixel according to a modification of the second embodiment of the present disclosure.

FIG. 10 is a cross-sectional view (part 5) for illustrating an example of a configuration of a pixel according to a modification of the second embodiment of the present disclosure.

FIG. 11A is an explanatory diagram (part 1) for illustrating a method of manufacturing the pixel according to the second embodiment of the present disclosure.

FIG. 11B is an explanatory diagram (part 2) for illustrating a method of manufacturing the pixel according to the second embodiment of the present disclosure.

FIG. 12 is a cross-sectional view for illustrating an example of a configuration of a pixel according to a third embodiment of the present disclosure.

FIG. 13 is a cross-sectional view (part 1) for illustrating an example of a configuration of a pixel according to a modification of the third embodiment of the present disclosure.

FIG. 14 is a cross-sectional view (part 2) for illustrating an example of a configuration of a pixel according to a modification of the third embodiment of the present disclosure.

FIG. 15 is a plan view (part 1) for illustrating an example of a configuration of a pixel according to a fourth embodiment of the present disclosure.

FIG. 16 is a plan view (part 2) for illustrating an example of the configuration of the pixel according to the fourth embodiment of the present disclosure.

FIG. 17A is an explanatory diagram (part 1) for illustrating a method of manufacturing a pixel according to a fifth embodiment of the present disclosure.

FIG. 17B is an explanatory diagram (part 2) for illustrating a method of manufacturing the pixel according to the fifth embodiment of the present disclosure.

FIG. 18A is an explanatory diagram (part 1) for illustrating a method of manufacturing a pixel according to a modification of the fifth embodiment of the present disclosure.

FIG. 18B is an explanatory diagram (part 2) for illustrating a method of manufacturing the pixel according to a modification of the fifth embodiment of the present disclosure.

FIG. 18C is an explanatory diagram (part 3) for illustrating a method of manufacturing the pixel according to a modification of the fifth embodiment of the present disclosure.

FIG. 19 is a cross-sectional view for illustrating an example of a configuration of a pixel according to a sixth embodiment of the present disclosure.

FIG. 20 is a cross-sectional view for illustrating an example of a configuration of a pixel according to a first modification of the sixth embodiment of the present disclosure.

FIG. 21 is a cross-sectional view for illustrating an example of a configuration of a pixel according to a second modification of the sixth embodiment of the present disclosure.

FIG. 22 is a cross-sectional view for illustrating an example of a configuration of a pixel according to a third modification of the sixth embodiment of the present disclosure.

FIG. 23 is a cross-sectional view for illustrating an example of a configuration of a pixel according to a fourth modification of the sixth embodiment of the present disclosure.

FIG. 24 is a cross-sectional view for illustrating an example of a configuration of a pixel according to a fifth modification of the sixth embodiment of the present disclosure.

FIG. 25 is a cross-sectional view for illustrating an example of a configuration of a pixel according to a sixth modification of the sixth embodiment of the present disclosure.

FIG. 26 is a cross-sectional view for illustrating an example of a configuration of a pixel according to a seventh modification of the sixth embodiment of the present disclosure.

FIG. 27 is an explanatory diagram for illustrating a method of manufacturing the pixel according to the sixth embodiment of the present disclosure.

FIG. 28A is a cross-sectional view for illustrating an example of a configuration of a subpixel according to a seventh embodiment of the present disclosure.

FIG. 28B is an enlarged view of a region A illustrated in FIG. 28A.

FIG. 29A is an explanatory diagram (part 1) for illustrating a method of manufacturing a subpixel according to the seventh embodiment of the present disclosure.

FIG. 29B is an explanatory diagram (part 2) for illustrating a method of manufacturing the subpixel according to the seventh embodiment of the present disclosure.

FIG. 30 is a cross-sectional view for illustrating an example of a configuration of a subpixel according to a first modification of the seventh embodiment of the present disclosure.

FIG. 31A is an explanatory diagram (part 1) for illustrating a method of manufacturing subpixel according to the first modification of the seventh embodiment of the present disclosure.

FIG. 31B is an explanatory diagram (part 2) for illustrating a method of manufacturing subpixel according to the first modification of the seventh embodiment of the present disclosure.

FIG. 32 is aross-sectional view for illustrating an example of a configuration of a subpixel according to a second modification of the seventh embodiment of the present disclosure.

FIG. 33A is an explanatory diagram (part 1) for illustrating a method of manufacturing subpixel according to a second modification of the seventh embodiment of the present disclosure.

FIG. 33B is an explanatory diagram (part 2) for illustrating a method of manufacturing subpixel according to the second modification of the seventh embodiment of the present disclosure.

FIG. 34A is a conceptual diagram (part 1) for illustrating a relationship among a normal line LN passing through a center of a light emitting portion, a normal line LN′ passing through a center of a lens member, and a normal line LN″ passing through a center of a wavelength selector.

FIG. 34B is a conceptual diagram (part 2) for illustrating a relationship among the normal line LN passing through the center of the light emitting portion, the normal line LN′ passing through the center of a lens member, and the normal line LN″ passing through the center of the wavelength selector.

FIG. 34C is a conceptual diagram (part 3) for illustrating a relationship among the normal line LN passing through the center of the light emitting portion, the normal line LN′ passing through the center of a lens member, and the normal line LN″ passing through the center of the wavelength selector.

FIG. 34D is a conceptual diagram (part 4) for illustrating a relationship among the normal line LN passing through the center of the light emitting portion, the normal line LN′ passing through the center of a lens member, and the normal line LN″ passing through the center of the wavelength selector.

FIG. 34E is a conceptual diagram (part 5) for illustrating a relationship among the normal line LN passing through the center of the light emitting portion, the normal line LN′ passing through the center of a lens member, and the normal line LN″ passing through the center of the wavelength selector.

FIG. 34F is a conceptual diagram (part 6) for illustrating a relationship among the normal line LN passing through the center of the light emitting portion, the normal line LN′ passing through the center of a lens member, and the normal line LN″ passing through the center of the wavelength selector.

FIG. 34G is a conceptual diagram (part 7) for illustrating a relationship among the normal line LN passing through the center of the light emitting portion, the normal line LN′ passing through the center of a lens member, and the normal line LN″ passing through the center of the wavelength selector.

FIG. 35 is a schematic cross-sectional view for illustrating a first example of a resonator structure.

FIG. 36 is a schematic cross-sectional view for illustrating a second example of the resonator structure.

FIG. 37 is a schematic cross-sectional view for illustrating a third example of the resonator structure.

FIG. 38 is a schematic cross-sectional view for illustrating a fourth example of the resonator structure.

FIG. 39 is a schematic cross-sectional view for illustrating a fifth example of the resonator structure.

FIG. 40 is a schematic cross-sectional view for illustrating a sixth example of the resonator structure.

FIG. 41 is a schematic cross-sectional view for illustrating a seventh example of the resonator structure.

FIG. 42A is a front view illustrating an example of an external appearance of a digital still camera.

FIG. 42B is a rear view illustrating an example of an external appearance of the digital still camera.

FIG. 43 is an external view of a head-mounted display.

FIG. 44 is an external view of a see-through head-mounted display.

FIG. 45 is an external view of a television device.

FIG. 46 is an external view of a smartphone.

FIG. 47A is a view (part 1) illustrating an internal configuration of an automobile.

FIG. 47B is a view (part 2) illustrating an internal configuration of the automobile.

### DESCRIPTION OF EMBODIMENTS

Preferred embodiments of the present disclosure will be described in detail hereinbelow with reference to the accompanying drawings. Note that redundant descriptions will be omitted from the present specification and the drawings by assigning the same reference signs to components having substantially the same functional configuration. Moreover, in the present specification and the drawings, a plurality of components having substantially the same or similar functional configuration will be distinguished by attaching different alphabets after the same reference numerals. However, when it is not particularly necessary to distinguish between the plurality of components having substantially the same or similar functional configuration, only the same reference numeral is given.

In addition, the drawings referred to in the following description are drawings for illustrating and facilitating further understanding of one embodiment of the present disclosure, and thus, shapes, dimensions, ratios, and the like illustrated in the drawings may be different from actual ones for the sake of clarity. Furthermore, an imaging device illustrated in the drawings can be appropriately changed in design in consideration of the following description and known techniques.

The description of specific lengths and shapes in the following description does not exclusively mean the same values as mathematically defined numerical values or geometrically defined shapes. Specifically, description of specific lengths and shapes in the following description includes dimensions in a case where there is a permissible difference (error/distortion) in the light emitting elements and the light emitting devices, manufacturing processes thereof, and use/operation thereof, and includes a shape similar to the shape illustrated herein.

In the following description of circuits (electrical connections), unless otherwise specified, “electrically connected” means that a connection is made to allow electrical (signal) conduction through a plurality of elements. In addition, “electrically connected” in the following description includes not only a case of directly and electrically connecting a plurality of elements but also a case of indirectly and electrically connecting a plurality of elements via other elements.

Note that the description will be provided in the following order.
1. Overall configuration of light emitting device according to embodiment of present disclosure
2. Background of creation of embodiments of present disclosure
3. First embodiment
4. Second embodiment
4.1 Detailed configuration
4.2 Modification
4.3 Manufacturing method
5. Third embodiment
5.1 Detailed configuration
5.2 Modification
6. Fourth embodiment
7. Fifth embodiment
7.1 Manufacturing method
7.2 Modification
8. Sixth embodiment
8.1 Detailed configuration
8.2 Modification
8.3 Manufacturing method
9. Seventh embodiment
9.1 Detailed configuration
9.2 First modification
9.3 Second modification
10. Summary
11. Modifications
11.1 First modification
11.2 Second modification
12. Application examples
13. Supplementary notes

### 1. Overall Configuration of Light Emitting Device According to Embodiment of Present Disclosure

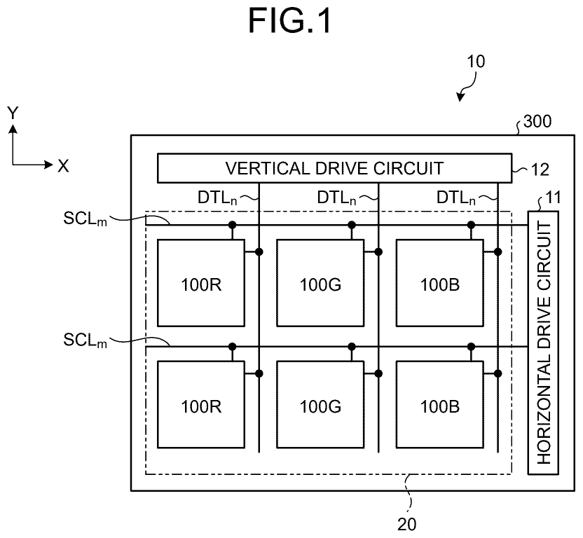

An example of an overall configuration of an organic electro-luminescence (EL) light emitting device 10 (hereinafter, simply referred to as a “light emitting device 10”) according to an embodiment of the present disclosure used as a display device or a lighting device will be described with reference to FIG. 1. FIG. 1 is a schematic diagram illustrating an example of the overall configuration of a light emitting device 10 according to the embodiment of the present disclosure.

The light emitting device 10 is, for example, a device including an array of light emitting elements such as an organic light emitting diode (OLED) or a micro-OLED. Such a light emitting device 10 is applicable to a display device such as a virtual reality (VR) display device, a mixed reality (MR) display device, or an augmented reality (AR) display device, an electronic view finder (EVF), or a small projector. The light emitting device 10 is also applicable to various lighting devices.

The light emitting device 10 includes: a display region; and a peripheral region provided on a peripheral edge of the display region. As illustrated in FIG. 1, the display region of the light emitting device 10 includes a plurality of subpixels 100R, 100G, and 100B arrayed in a matrix, for example. The subpixel 100R can emit red light, the subpixel 100G can emit green light, and the subpixel 100B can emit blue light. In the following description, the subpixels 100R, 100G, and 100B are referred to as subpixels 100 unless specific distinction is needed.

Furthermore, in the present embodiment, one pixel 20 includes a combination of the three types of subpixels 100R, 100G, and 100B that emit different colors of light, for example. In the present embodiment, the individual numbers and layout of the three types of subpixels 100R, 100G, and 100B included in one pixel 20 are not particularly limited. Furthermore, in the present embodiment, one pixel 20 is not limited to including the plurality of subpixels 100 that emit different colors of light as described above, and may include a plurality of subpixels 100 that emit light of an identical color. Furthermore, the pixel 20 represents a minimum unit (unit pixel) controlled at the time of light emission control of the light emitting device 10, and includes a plurality of subpixels 100 treated as one unit at the time of control. That is, in the present embodiment, the light emitting device 10 includes the plurality of pixels 20 arrayed in a matrix on a substrate 300.

As illustrated in FIG. 1, a horizontal drive circuit 11 and a vertical drive circuit 12 are provided in a peripheral region of the light emitting device 10.

The horizontal drive circuit 11 can scan each subpixel 100 in units of rows (in FIG. 1, a direction extending in the X direction is denoted as a row direction) when writing a signal to each subpixel 100, and sequentially supply a scanning signal to each scanning line SCLₘ. The horizontal drive circuit 11 can include a device such as a shift register, for example, to sequentially shift (transfer) a start pulse in synchronization with a clock pulse to be input.

The vertical drive circuit 12 can supply a signal voltage of a signal corresponding to luminance information supplied from a signal supply source (not illustrated) to the subpixels 100 selected in units of columns (in FIG. 1, a direction extending in the Y direction is denoted as a column direction) via the signal line DTLₙ.

In the embodiment of the present disclosure, the configuration of the light emitting device 10 is not limited to the configuration illustrated in FIG. 1. That is, the configuration illustrated in FIG. 1 is merely an example, and the light emitting device 10 according to the embodiment of the present disclosure can adopt various configurations.

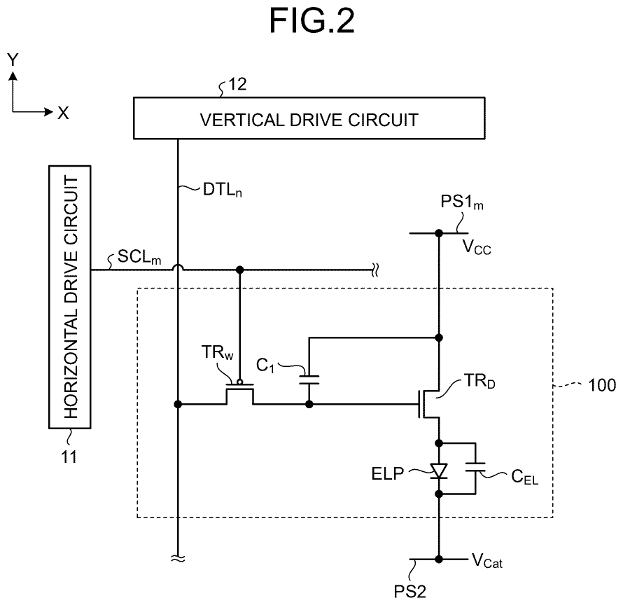

Next, a circuit configuration of the subpixel 100 in the mth row and the nth column will be described with reference to FIG. 2. FIG. 2 is a schematic circuit diagram for illustrating a connection relationship in the subpixel 100 in the mth row and the nth column.

In the light emitting device 10, as described above, the subpixels 100 including the light emitting elements ELP are arrayed in a two-dimensional matrix in a state of being connected to the scanning line SCLₘ extending in the row direction (X direction in FIG. 1) and the signal line DTLₙ extending in the column direction (Y direction in FIG. 1).

Furthermore, as illustrated in FIG. 2, the light emitting device 10 includes a power feed line PS1ₘ to supply a drive voltage to the subpixel 100, and a common power feed line PS2 to be commonly connected to all the subpixels 100. The power feed line PS1ₘ has a predetermined drive voltage V_{cc} or the like supplied from a power source (not illustrated), while the common power feed line PS2 has a common voltage V_{cat} (for example, ground potential) supplied from the power source.

Here, the number of the scanning lines SCL and the number of the power feed lines PS1 are each set to M. The subpixels 100 in the mth row (where m=1, 2 . . . , P) are connected to the mth scanning line SCLₘ and the mth power feed line PS1ₘ, constituting one display element row. Note that FIG. 2 illustrates only the scanning line SCLₘ and the power feed line PS1ₘ. The number of signal lines DTL is set to N. The subpixel 100 in the nth column (where n=1, 2 . . . , N) is connected to the nth signal line DTLₙ. Note that FIG. 2 illustrates only the signal line DTLₙ. Hereinafter, the subpixel 100 located in the mth row and the nth column may be referred to as a (n, m)th subpixel 100.

As described above, the light emitting device 10 is sequentially scanned in units of rows by the scanning signal from the horizontal drive circuit 11. Specifically, in the light emitting device 10, M subpixels 100 arrayed in the mth row are simultaneously driven. In other words, in the M subpixels 100 arranged in the row direction, the light emission/non-light emission timing is controlled in units of rows to which they belong. For example, when a display frame rate of the light emitting device 10 is FR (times/second), a scanning period per row (also referred to as a horizontal scanning period) when the light emitting device 10 is sequentially scanned in units of rows is less than (1/FR)×(1/P) seconds.

As illustrated in FIG. 2, the subpixel 100 includes a light emitting element ELP and a drive circuit to drive the light emitting element ELP. The light emitting element ELP is formed of an organic electro-luminescence light emitting element. The drive circuit includes a write transistor TR_{w}, a drive transistor TR_{D}, and a capacitor C₁. When a current flows through the light emitting element ELP via the drive transistor TR_{D}, the light emitting element ELP can emit light. Each transistor includes a p-channel field effect transistor, for example.

As illustrated in FIG. 2, in the subpixel 100, one source/drain region of the drive transistor TR_{D} is electrically connected to one end of the capacitor C₁ and to the power feed line PS1ₘ, while the other source/drain region is electrically connected to one end (specifically, an anode electrode) of the light emitting element ELP. A gate electrode of the drive transistor TR_{D} is connected to the other source/drain region of the write transistor TR_{w}, and is electrically connected to the other end of the capacitor C₁.

Furthermore, as illustrated in FIG. 2, one source/drain region of the write transistor TR_{w} is electrically connected to the signal line DTLₙ, while the gate electrode of the write transistor TR_{w} is electrically connected to the scanning line SCLₘ.

In addition, as illustrated in FIG. 2, the other end (specifically, the cathode electrode) of the light emitting element ELP is electrically connected to the common power feed line PS2. Furthermore, the common power feed line PS2 has a supply of a predetermined cathode voltage V_{cat}. In FIG. 2, the capacitance of the light emitting element ELP is represented by a reference sign C_{EL}.

An outline of driving of the subpixel 100 will be described. In the subpixel 100, when the write transistor TR_{w} is brought into a conductive state by the scanning signal from the horizontal drive circuit 11 in a state where the voltage corresponding to the luminance of the image to be displayed on the signal line DTLₙ is supplied from the vertical drive circuit 12, the voltage corresponding to the luminance is written into the capacitor C₁. After the write transistor TR_{w} is brought into a non-conductive state, a current flows through the drive transistor TR_{D} according to the voltage held in the capacitor C₁, allowing the light emitting element ELP to emit light.

In the embodiment of the present disclosure, the configuration of the drive circuit that controls the light emission of the light emitting element ELP is not limited to the configuration illustrated in FIG. 2. Accordingly, the configuration illustrated in FIG. 2 is merely an example, and the light emitting device 10 according to the embodiment of the present disclosure can use various configurations.

### 2. Background of Creation of Embodiments of Present Disclosure

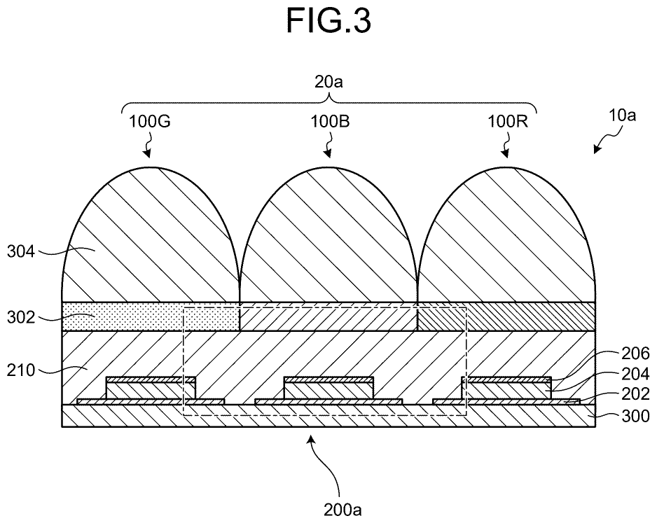

First, before describing details of the embodiment of the present disclosure, the background leading to the creation of the embodiment of the present disclosure by the present inventors will be described with reference to FIG. 3. FIG. 3 is a cross-sectional view for illustrating an example of a configuration of a pixel 20a according to a comparative example. Here, the comparative example represents the pixel 20a that has been studied by the present inventors before conceiving the embodiment of the present disclosure.

As described above, a light emitting device 10a according to the comparative example includes a plurality of the pixels 20a, and for example, the pixel 20a is configured by a combination of three types of subpixels 100R, 100G, and 100B as illustrated in FIG. 3. Here, the subpixel 100R can emit red light, the subpixel 100G can emit green light, and the subpixel 100B can emit blue light. In the comparative example, the individual numbers and layout of the three types of subpixels 100R, 100G, and 100B included in one pixel 20a are not particularly limited.

Furthermore, as illustrated in FIG. 3, each subpixel 100 includes a light emitting element 200a. The light emitting element 200a includes: an anode electrode (first electrode) 202 provided on a substrate 300; a light emitting layer 204 stacked on the anode electrode 202; and a cathode electrode (second electrode) 206 stacked on the light emitting layer 204 and transmitting light from the light emitting layer 204.

As illustrated in FIG. 3, the subpixel 100 is covered with a protective film 210. On the protective film 210, there are provided a color filter 302 and an on-chip lens 304, for each subpixel 100.

In the pixel 20a according to such a comparative example, when a predetermined voltage is supplied to the anode electrode 202 and the cathode electrode 206, the light emitting layer 204 sandwiched between the anode electrode 202 and the cathode electrode 206 emits light. Specifically, in the comparative example, light is emitted from the light emitting layer 204 in a direction from the anode electrode 202 toward the cathode electrode 206. In other words, the light emitting device 10a according to the comparative example is a top emission type light emitting device.

The present inventors have intensively studied to further improve a light extraction efficiency, that is, the efficiency to extract light from each subpixel 100 in the pixel 20a configured in this manner. According to the study of the present inventors, in the subpixel 100 according to the comparative example, the light from the light emitting layer 204 has a large radiation angle and is widely diffused, having a limit in improving the upward light extraction efficiency in FIG. 3 of the light emitting device 10a.

In view of this, the present inventors have found that narrowing the spread of light from the light emitting layer 204 (in other words, reducing the radiation angle) to enable the light to be efficiently guided upward will further improve the light extraction efficiency of the light emitting device 10a, and have conceived the embodiment of the present disclosure described below. Hereinafter, details of embodiments of the present disclosure created by the present inventors will be sequentially described.

### 3. First Embodiment

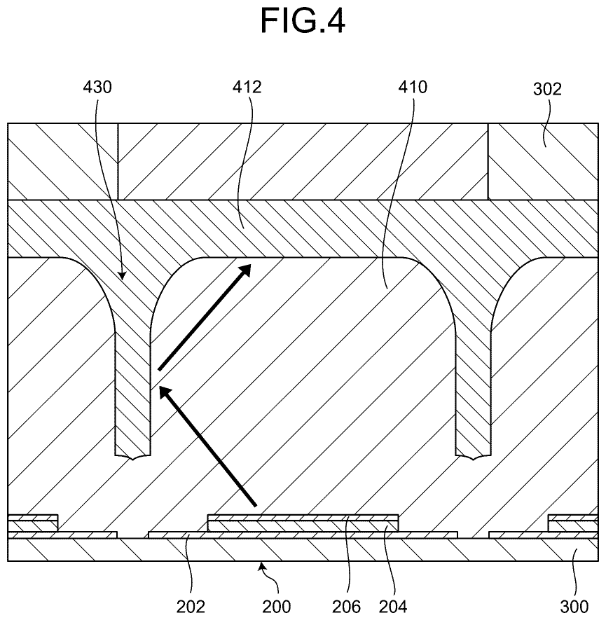

First, a first embodiment of the present disclosure created by the present inventors will be described with reference to FIG. 4. FIG. 4 is a cross-sectional view for illustrating an example of the configuration of the pixel 20 according to the present embodiment, and is an enlarged view of a corresponding region of a region surrounded by a broken line in FIG. 3. Specifically, FIG. 4 is a cross-sectional view when a light emitting element 200 of the subpixel 100 is cut in a direction perpendicular to the plane of the substrate 300.

First, as illustrated in FIG. 4, in the present embodiment, the pixel 20 is configured by combining three types of subpixels 100R, 100G, and 100B that emit light of different colors, for example, similarly to the comparative example. Here, it is assumed that the subpixel 100R can emit red light (for example, visible light having a wavelength of about 640 nm to 770 nm), the subpixel 100G can emit green light (for example, visible light having a wavelength of about 490 nm to 550 nm), and the subpixel 100B can emit blue light (for example, visible light having a wavelength of about 430 nm to 490 nm). Also in the present embodiment, the individual numbers and layout of the three types of subpixels 100R, 100G, and 100B included in one pixel 20 are not limited. Furthermore, in the present embodiment, the pixel 20 may include a subpixel 100 that emits light other than red light, blue light, and green light. In addition, in the present embodiment, each subpixel 100 included in the pixel 20 may emit light of an identical color.

Also in the present embodiment, each subpixel 100 includes the light emitting element 200 similarly to the comparative example. In the present embodiment, the shape of the light emitting element 200 is, for example, a rectangular shape when viewed from above the substrate 300 (in plan view). In the present embodiment, the shape of the light emitting element 200 in a plan view is not limited to a rectangular shape, and may be other shapes such as a polygonal shape (specifically, for example, a hexagon or the like), a circular shape, and an elliptical shape.

Furthermore, as illustrated in FIG. 4, similarly to the comparative example, each light emitting element 200 includes: an anode electrode (first electrode) 202 provided on a substrate 300; a light emitting layer 204 stacked on the anode electrode 202 and configured to emit light; and a cathode electrode (second electrode) 206 stacked on the light emitting layer 204 and transmitting light from the light emitting layer 204.

Specifically, the substrate 300 can be formed of a substrate, for example: a glass substrate such as high strain point glass, soda glass, borosilicate glass, forsterite, lead glass, or quartz glass; a semiconductor substrate such as amorphous silicon or polycrystalline silicon; a resin substrate such as polymethyl methacrylate, polyvinyl alcohol, polyvinyl phenol, polyether sulfone, polyimide, polycarbonate, polyethylene terephthalate, or polyethylene naphthalate.

In addition, the anode electrode 202 of the light emitting element 200 may also have a function as a reflection layer, and is preferably formed of a metal film having as high a reflectance as possible and a large work function in order to enhance light extraction efficiency. Examples of such a metal film include a metal film containing at least one of a simple substance and an alloy of metal elements such as chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). Specific examples of the alloy include: an aluminum alloy (Al alloy) such as an AlNi alloy or an AlCu alloy; and a silver alloy (Ag alloy) such as an MgAg alloy. The anode electrode 202 may be formed of a transparent conductive film such as indium tin oxide (ITO), indium zinc oxide (IZO), or zinc oxide (ZnO). Furthermore, the anode electrode 202 may be a stacked film including two or more films described above.

Furthermore, in the present embodiment, the anode electrode 202 of one light emitting element 200 may be connected to the anode electrode 202 of the adjacent light emitting element 200.

The light emitting layer 204 provided on the anode electrode 202 is a layer formed of an organic material or an inorganic material, and capable of emitting white light, for example. The light emitting layer 204 may include: a hole injection layer (not illustrated) and a hole transport layer (not illustrated) adjacent to the anode electrode 202; and an electron transport layer (not illustrated) adjacent to the cathode electrode 206. In other words, the light emitting layer 204 can have a structure in which a hole injection layer, a hole transport layer, the light emitting layer 204, and an electron transport layer (not illustrated) are stacked from the anode electrode 202 side. The hole injection layer functions as a layer to enhance an efficiency of hole injection into the light emitting layer 204, and also functions as a buffer layer for suppressing leakage. The hole transport layer functions as a layer to enhance efficiency of hole transport to the light emitting layer 204. In the light emitting layer 204, generation of an electric field recombines electrons and holes, achieving emission of light. The electron transport layer functions as a layer to increase efficiency of electron transport to the light emitting layer 204. Furthermore, the light emitting layer 204 may have an electron injection layer (not illustrated) between the electron transport layer and the cathode electrode 206. The electron injection layer functions as a layer to enhance electron injection efficiency.

Note that, in the present embodiment, the configuration of the light emitting layer 204 is not limited to the above-described configuration, and layers other than the hole injection layer and the light emitting layer 204 can be provided as necessary. Furthermore, in the present embodiment, the light emitting layer 204 may be configured to emit light of a color other than white light. For example, light emitting layer 204 may emit red light, green light, and blue light. In the present embodiment, the light emitting layers 204 of the light emitting elements 200 of all the subpixels 100 may have an identical structure or mutually different structures, with no particular limitation.

In addition, the cathode electrode 206 provided on the light emitting layer 204 is a transparent electrode having transparency to light generated in the light emitting layer 204, and the transparent electrode also includes a semi-transparent electrode in the following description. The cathode electrode 206 can be formed of a metal film containing at least one of a simple substance or an alloy of a metal element such as aluminum (Al), magnesium (Mg), calcium (Ca), sodium (Na), or silver (Ag). Specific examples of the alloy include an aluminum alloy (Al alloy) such as an MgAg alloy or an AlLi alloy, and a silver alloy (Ag alloy). The cathode electrode 206 may be formed of a transparent conductive film such as indium tin oxide (ITO), indium zinc oxide (IZO), or zinc oxide (ZnO). Furthermore, the cathode electrode 206 may be a stacked film of two or more films described above.

Furthermore, in the present embodiment, the cathode electrode 206 of one light emitting element 200 may be connected to the cathode electrode 206 of the adjacent light emitting element 200.

Furthermore, in the present embodiment, a protective film 410 (first protective film), being a film transmitting light from the light emitting layer 204, is stacked on the cathode electrode 206. Specifically, the protective film 410 is continuously provided on the cathode electrodes 206 of the adjacent light emitting elements 200. In other words, the protective film 410 is provided as one layer common to each light emitting element 200.

In addition, the protective film 410 is formed of a material having a high refractive index. For example, the protective film 410 is preferably formed of a material having a refractive index of about 1.7 to 2.1 to light having a wavelength of about 450 nm at room temperature, for example. Specifically, the protective film 410 can be formed of, for example, a nitride film such as silicon nitride (SiN), a transparent conductive film such as indium tin oxide (ITO), indium zinc oxide (IZO), or zinc oxide (ZnO), a transparent organic film, or the like.

Furthermore, in the present embodiment, unlike the comparative example, the protective film 410 is provided with a trenches (first trench) 430 so as to partition the adjacent light emitting elements 200 (or the subpixels 100). Specifically, the trench 430 is located between the adjacent light emitting elements 200. In addition, in the present embodiment, in a cross section (cross-sectional view) obtained by cutting in a direction perpendicular to the plane of the substrate 300, the trench 430 is provided so as to penetrate from the upper surface toward the lower surface of the protective film 410 partway through the film thickness of the protective film 410. Here, the lower surface of the protective film 410 is a surface on the light emitting element 200 side, and the upper surface of the protective film 410 is a surface opposite the lower surface. In addition, in the present embodiment, the shape of the trench 430 is not particularly limited. However, for example, in the cross section, the trench 430 may have a tapered shape, being a shape expanding toward the upper direction, and the contour line of the expanding region is preferably curved. Furthermore, in the present embodiment, the depth of the trench 430 is not particularly limited, but is preferably deeper from the upper surface toward the lower surface of the protective film 410.

In the present embodiment, the trench 430 has an embedded film, being a protective film 412 formed of a low refractive index film lower in the refractive index than the protective film 410. For example, the protective film 412 is to be formed of a material lower in the refractive index than the protective film 410, and specifically, is preferably formed of a material with a refractive index having a difference (refractive index difference) of 0.2 or less, for example, with respect to the protective film 410. More specifically, the protective film 412 can be formed of a film, for example, an oxide film such as silicon oxide (SiO₂) and aluminum oxide (Al₂O₃), and a resin film.

In the present embodiment, the trench 430 is provided in the protective film 410 on the light emitting element 200 so as to partition the adjacent light emitting elements 200, and the protective film 412 having a refractive index lower than the refractive index of the protective film 410 is embedded in the trench 430. With this configuration of the present embodiment, the light of the light emitting layer 204 is reflected at an interface between the protective film 410 and the protective film 412 (arrow in FIG. 4). Furthermore, in the present embodiment, by being bound by the protective film 410 and the protective film 412, the light beams from the light emitting layer 204 are reflected many times at the interface so as to be confined in the protective film 410 to interfere with each other. Accordingly, in the present embodiment, the protective film 410 sandwiched between the trenches 430 functions like a waveguide, and can guide the light from the light emitting layer 204 upward while Suppressing spreading of the light. As a result, in the present embodiment, it is possible to improve the upward light extraction efficiency of the light emitting device 10.

Furthermore, in the present embodiment, the protective film 412 is provided so as to cover the upper surface of the protective film 410.

In addition, in the present embodiment, similarly to the comparative example, there are provided the color filter 302 and the on-chip lens 304 for each subpixel 100. Specifically, as illustrated in FIG. 4, in the present embodiment, one on-chip lens 304 (not illustrated in FIG. 4) is provided above the light emitting element 200 included in one subpixel 100, and one color filter 302 is provided between the protective film 412 and the on-chip lens 304.

Specifically, the color filter 302 can include a color filter that transmits a red wavelength component, a color filter that transmits a green wavelength component, or a color filter that transmits a blue wavelength component. For example, the color filter 302 can be formed of a material having a refractive index of about 1.6 to 1.7, and specifically, for example, can be formed of a material in which a pigment or a dye is dispersed in a transparent binder such as silicone. The on-chip lens 304 can be formed of a material such as a styrene-based resin, an acrylic resin, a styrene-acrylic copolymer-based resin, or a siloxane-based resin. In the present embodiment, the color filter 302 can be omitted.

As described above, in the present embodiment, the trench 430 is provided in the protective film 410 on the light emitting element 200 so as to partition the adjacent light emitting elements 200, and the protective film 412 having a refractive index lower than the refractive index of the protective film 410 is embedded in the trench 430. With this configuration, in the present embodiment, by being bound by the protective film 410 and the protective film 412, the light beams from the light emitting layer 204 are reflected many times at the interface so as to be confined in the protective film 410 to interfere with each other. Accordingly, in the present embodiment, the protective film 410 sandwiched between the trenches 430 functions like a waveguide, and can guide the light from the light emitting layer 204 upward while suppressing spreading of the light. As a result, in the present embodiment, it is possible to improve the upward light extraction efficiency of the light emitting device 10.

The present embodiment is not limited to the configuration illustrated in FIG. 4, and can be appropriately modified in accordance with desired characteristics and the like.

### 4. Second Embodiment

### 4.1 Detailed Configuration

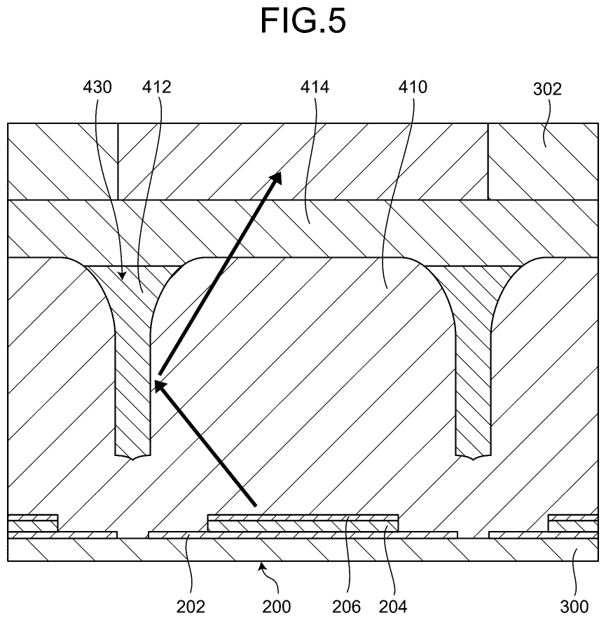

Next, a second embodiment of the present disclosure will be described with reference to FIG. 5. FIG. 5 is a cross-sectional view for illustrating an example of the configuration of the pixel 20 according to the present embodiment, and is an enlarged view of a corresponding region of a region surrounded by a broken line in FIG. 3. Specifically, FIG. 5 is a cross-sectional view when the light emitting element 200 of the subpixel 100 is cut in a direction perpendicular to the plane of the substrate 300.

Meanwhile, after intensive studies by the present inventors to further improve the light extraction efficiency, it has been found that, even with the fact that the first embodiment of the present disclosure can improve the upward light extraction efficiency, there is a limit to improvement of the efficiency.

Specifically, in the first embodiment of the present disclosure, there is a case where a part of light from the light emitting layer 204 is reflected at the interface between the protective film 410 and the protective film 412 located above the light emitting element 200, and the light is confined in the protective film 410 sandwiched between the trenches 430. This causes, in the first embodiment, limited improvement in upward light extraction efficiency.

Furthermore, the protective film 412, being a film with a low refractive index, has coarse film quality, and is likely to cause a process damage in the manufacturing process of the light emitting device 10. Therefore, in order to improve the yield of the light emitting device 10, avoiding process damage to the protective film 412 is necessary.

Therefore, in view of such a situation, the present inventors have created the second embodiment of the present disclosure described below, in which the protective film 412 in the trench 430 is covered with a high refractive index film to suppress occurrence of a process damage in the protective film 412 in the manufacturing process while further improving the upward light extraction efficiency. Hereinafter, details of the second embodiment of the present disclosure created by the present inventors will be sequentially described. The following description will omit description overlapping the description of the first embodiment.

In the present embodiment, as illustrated in FIG. 5, each light emitting element 200 includes: an anode electrode (first electrode) 202 provided on a substrate 300; a light emitting layer 204 stacked on the anode electrode 202 and configured to emit light; and a cathode electrode (second electrode) 206 stacked on the light emitting layer 204 and transmitting light from the light emitting layer 204.

Also in the present embodiment, similarly to the first embodiment, the protective film (first protective film) 410 is to be continuously provided on the cathode electrodes 206 of the adjacent light emitting elements 200, and the protective film 410 is preferably formed of a material having a high refractive index, similarly to the first embodiment.

Also in the present embodiment, similarly to the first embodiment, there are provided, in the protective film 410, trenches 430 to partition the adjacent light emitting elements 200. The trench 430 is located between the adjacent light emitting elements 200 and is provided so as to penetrate from the upper surface to the lower surface of the protective film 410 partway through the film thickness of the protective film 410. In the present embodiment, similarly to the first embodiment, the trench 430 has an embedded film, being a protective film 412 formed of a low refractive index film lower in the refractive index than the protective film 410.

Furthermore, in the present embodiment, unlike the first embodiment, a protective film (second protective film) 414 is provided so as to cover the upper surface of the protective film 410, that is, so as to be in contact with the protective film 410. In the example of FIG. 5, the protective film 414 is provided so as to cover the upper surface of the protective film 412 in the trench 430.

The protective film 414 is formed of a material having a high refractive index. The protective film 414 preferably is formed of a material having a refractive index higher than a refractive index of the protective film 412 and having a refractive index equivalent to or lower than the refractive index of the protective film 410. The protective film 414 more preferably has a refractive index between the refractive index of the protective film 410 and the refractive index of the color filter 302. For example, the protective film 414 can be formed of, for example, a material having a refractive index of about 1.6 to 1.8. Specifically, the protective film 414 can be formed of, for example, a nitride film such as silicon nitride (SiN), a transparent conductive film such as indium tin oxide (ITO), indium zinc oxide (IZO), or zinc oxide (ZnO), a transparent organic film, or the like.

In the present embodiment, by providing the protective film 414 formed of a material having a high refractive index on the protective film 410 on the light emitting element 200, it is possible to suppress reflection of light from the light emitting layer 204 at an interface between the protective film 410 and the protective film 414 located above the light emitting element 200. Therefore, according to the present embodiment, it is possible to suppress confinement of light in the protective film 410 sandwiched between the trenches 430, achieving further improvement of the upward light extraction efficiency.

Furthermore, in the present embodiment, by providing the protective film 414 so as to cover the upper surface of the protective film 412 in the trench 430, it is possible to suppress occurrence of process damage in the manufacturing process to the protective film 412 having a coarse film quality, for example.

Furthermore, also in the present embodiment, similarly to the first embodiment, the color filter 302 and the on-chip lens 304 are provided for each subpixel 100. Also in the present embodiment, the color filter 302 can be omitted.

As described above, in the present embodiment, by providing the protective film 414 formed of a material having a high refractive index on the protective film 410 on the light emitting element 200, it is possible to suppress reflection of light from the light emitting layer 204 at an interface between the protective film 410 and the protective film 414 located above the light emitting element 200. Therefore, according to the present embodiment, it is possible to suppress confinement of light in the protective film 410 sandwiched between the trenches 430, achieving further improvement of the upward light extraction efficiency. Furthermore, in the present embodiment, by providing the protective film 414 so as to cover the upper surface of the protective film 412 in the trench 430, it is possible to suppress occurrence of process damage in the manufacturing process to the protective film 412.

The present embodiment is not limited to the configuration illustrated in FIG. 5, and can be appropriately modified in accordance with desired characteristics and the like.

### 4.2 Modifications

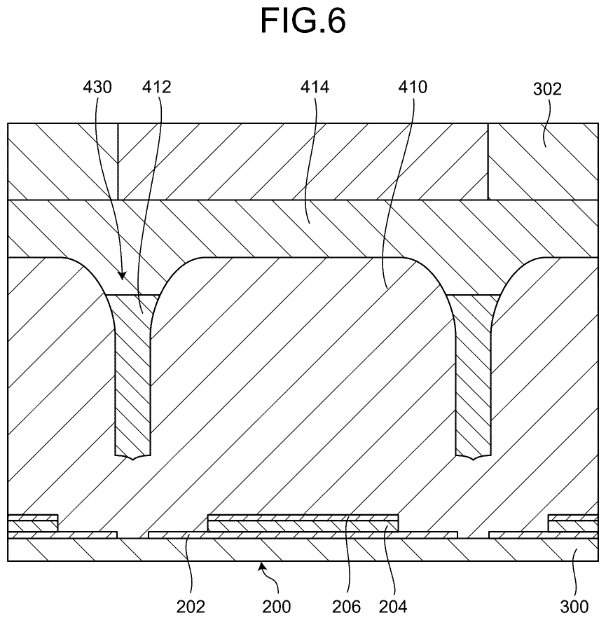

Hereinafter, modifications of the present embodiment will be described with reference to FIGS. 6 to 10. FIGS. 6 to 10 are cross-sectional views for illustrating an example of the configuration of the pixel 20 according to modifications of the present embodiment, and is an enlarged view of a corresponding region of a region surrounded by a broken line in FIG. 3. Specifically, FIGS. 6 to 10 are cross-sectional views when the light emitting element 200 of the subpixel 100 is cut in a direction perpendicular to the plane of the substrate 300.

First, as illustrated in FIG. 6, the protective film 414 may be provided so as to be embedded in a part of the trench 430. With this configuration, in the cross section (cross-sectional view) when cut in a direction perpendicular to the plane of the substrate 300, the protective film 410 and the protective film 414 come in contact with each other at the corner of the upper surface of the protective film 410 located above the light emitting element 200. Therefore, the present modification suppresses reflection of light at the corner of the upper surface of the protective film 410, making it possible to suppress confinement of light in the protective film 410 sandwiched between the trenches 430, further improving the upward light extraction efficiency.

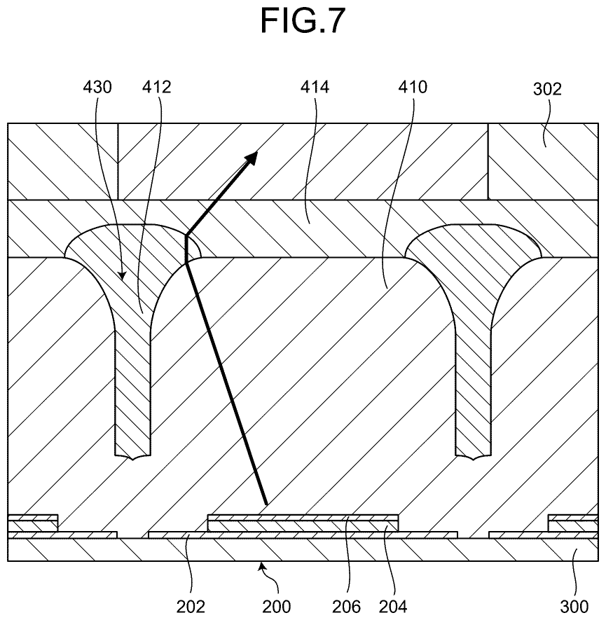

Next, as illustrated in FIG. 7, the protective film 412 may protrude from the trench 430. Furthermore, the shape of a part of the protective film 412 protruding from the trench 430 may be a lens shape. With this configuration, a part of the end of the protective film 412 protruding from the trench 430 functions like a lens, making it possible to diffract the light incident on a part of the protective film 412 protruding from the trench 430, and to guide the light to the upper side of the light emitting element 200 (refer to an arrow in FIG. 7). Accordingly, the present modification makes it possible to further improve the upward light extraction efficiency.

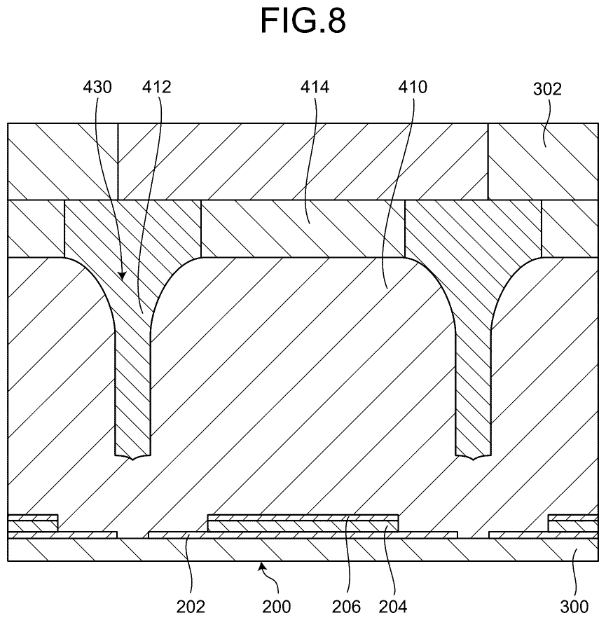

Next, as illustrated in FIG. 8, the protective film 412 may protrude from the trench 430 to penetrate and divide the protective film 414. With this configuration, the light beams from the light emitting layer 204 are reflected at the interface between the protective film 412 and the protective film 414 so as to be confined in the protective film 414 to interfere with each other. Therefore, in the present modification, the protective film 414 sandwiched between the protective films 412 functions like a waveguide, and can guide the light from the light emitting layer 204 upward while suppressing spreading of the light. As a result, the present modification can improve the upward light extraction efficiency.

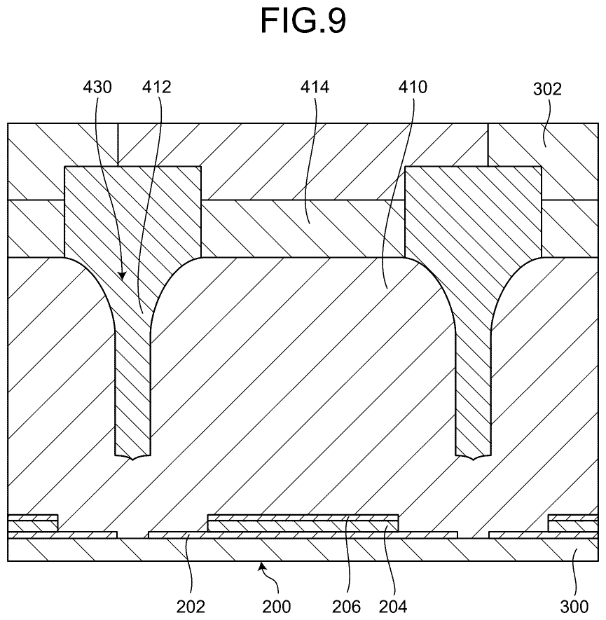

In addition, as illustrated in FIG. 9, the protective film 412 may protrude from the trench 430, penetrate the protective film 414, and penetrate partway through the film thickness of the color filter 302. In other words, a part of the protective film 412 may be in contact with the color filter 302. Also in the present modification, similarly to the example in FIG. 8, the light beams from the light emitting layer 204 are reflected at the interface between the protective film 412 and the protective film 414 so as to be confined in the protective film 414 to interfere with each other. Furthermore, also in the present modification, light is reflected also at the interface between the protective film 412 and the color filter 302 so as to be confined in the color filter 302 to interfere with each other. Therefore, in the present modification, the protective film 414 and the color filter function like a waveguide, and can guide the light from the light emitting layer 204 upward while suppressing spreading of the light. As a result, the present modification can improve the upward light extraction efficiency.

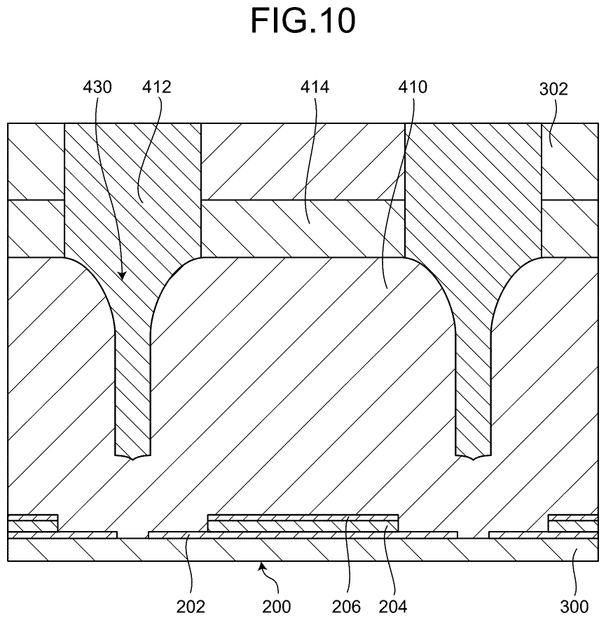

As illustrated in FIG. 10, the protective film 412 may protrude from the trench 430, penetrate the protective film 414, and penetrate the color filter 302 to divide the color filter 302. Also in the present modification, similarly to the example of FIG. 9, since light is reflected at the interface between the protective film 412 and the protective film 414 and the interface between the protective film 412 and the color filter 302, the protective film 414 and the color filter function like a waveguide, and can guide light from the light emitting layer 204 upward while suppressing spreading of the light. As a result, the present modification can improve the upward light extraction efficiency.

The modifications of the present embodiment are not limited to the configurations illustrated in FIGS. 6 to 10, and can be appropriately modified in accordance with desired characteristics and the like.

### 4.3 Manufacturing Method

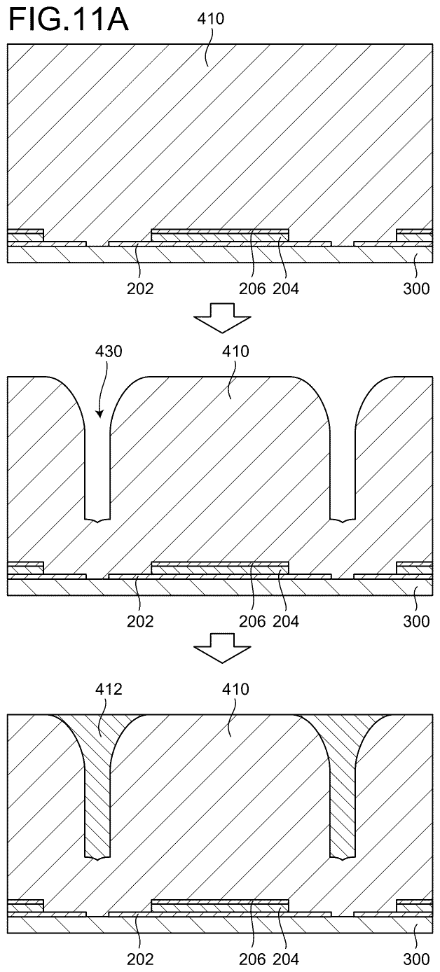

Next, an example of a method of manufacturing the pixel 20 of the present embodiment will be described with reference to FIGS. 11A and 11B. FIGS. 11A and 11B are explanatory diagrams for illustrating the method of manufacturing the pixel 20 of the present embodiment, and correspond to the cross-sectional view of FIG. 5.

First, as illustrated in the upper drawing of FIG. 11A, the patterned anode electrode 202 is formed on the substrate 300, and the light emitting layer 204 and the cathode electrode 206 are sequentially stacked on the anode electrode 202. Furthermore, a protective film 410 is stacked on the cathode electrode 206. Next, as illustrated in the middle drawing of FIG. 11A, a mask having a predetermined pattern is formed on the protective film 410 by photolithography, etching is performed according to the pattern of the mask to form the trench 430 in the protective film 410. Furthermore, as illustrated in the lower drawing of FIG. 11A, the protective film 412 is formed in the trench 430, and then the upper surface of the protective film 412 is planarized by a technique such as chemical mechanical polishing (CMP).

Next, as illustrated in the upper drawing of FIG. 11B, the protective film 414 is formed on the protective film 410 and the protective film 412, and the upper surface of the protective film 414 is planarized by a technique such as CMP. Furthermore, as illustrated in the lower drawing of FIG. 11B, the color filter 302 is formed on the protective film 414. The pixel 20 of the present embodiment can be formed in this manner.

The manufacturing method described here is an example, and can be appropriately changed in the present embodiment.

### 5. Third Embodiment

### 5.1 Detailed Configuration

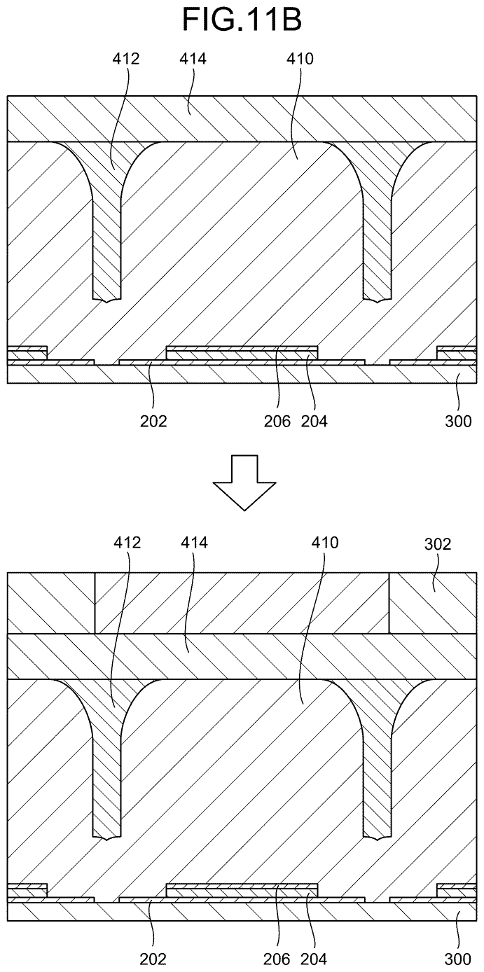

Next, a third embodiment of the present disclosure will be described with reference to FIG. 12. The present embodiment is an embodiment including wiring (first wiring) 208 electrically connecting the cathode electrodes 206 of adjacent light emitting elements 200 to each other. FIG. 12 is a cross-sectional view for illustrating an example of the configuration of the pixel 20 according to the present embodiment, and is an enlarged view of a corresponding region of a region surrounded by a broken line in FIG. 3. Specifically, FIG. 12 is a cross-sectional view when the light emitting element 200 of the subpixel 100 is cut in a direction perpendicular to the plane of the substrate 300.

Specifically, as illustrated in FIG. 12, in the present embodiment, the protective film 410 has a contact hole 432 exposing a part of the upper surface of the cathode electrode 206 based on the configuration of the above-described second embodiment. Furthermore, the wiring 208 is provided so as to cover at least a part of the side surface of the contact hole 432. The wiring 208 is electrically connected to the upper surface of the cathode electrode 206 exposed from the contact hole 432. In addition, in a cross section (cross-sectional view) when cut in a direction perpendicular to the plane of the substrate 300, the wiring 208 extends so as to pass below the trench 430 and further extends so as to cover the side surface of the contact hole 432 of the adjacent light emitting element 200. This makes it possible for the wiring 208 to electrically connect the cathode electrodes 206 of the adjacent light emitting elements 200 to each other. The wiring 208 can be formed of, for example, a transparent conductive film such as indium tin oxide (ITO), indium zinc oxide (IZO), or zinc oxide (ZnO).

In the present embodiment, as illustrated in FIG. 12, the protective film 410 is embedded in the contact hole 432 so as to cover the wiring 208 on the side surface of the contact hole 432. Furthermore, in the present embodiment, the protective film 412 is embedded in the center portion of the contact hole 432 so as to cover the protective film 410. In other words, in the present embodiment, the wiring 208 on the side surface of the contact hole 432 is covered with a stack of the protective film 410 and the protective film 412.

In the present embodiment with this configuration, the light beams from the light emitting layer 204 are reflected at the interface between the protective film 410 and the protective film 412, so as to be confined in the protective film 410 to interfere with each other. This allows the protective film 410 to function like a waveguide, making it possible to guide the light from the light emitting layer 204 upward while suppressing spreading of the light. As a result, the present embodiment can improve the upward light extraction efficiency.

Note that the present embodiment is not limited to the configuration as illustrated in FIG. 12, and can be appropriately modified in accordance with desired characteristics and the like.

### 5.2 Modifications

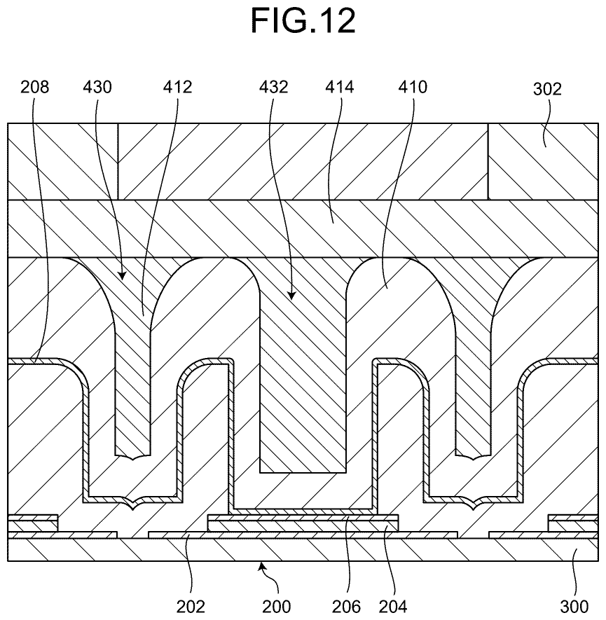

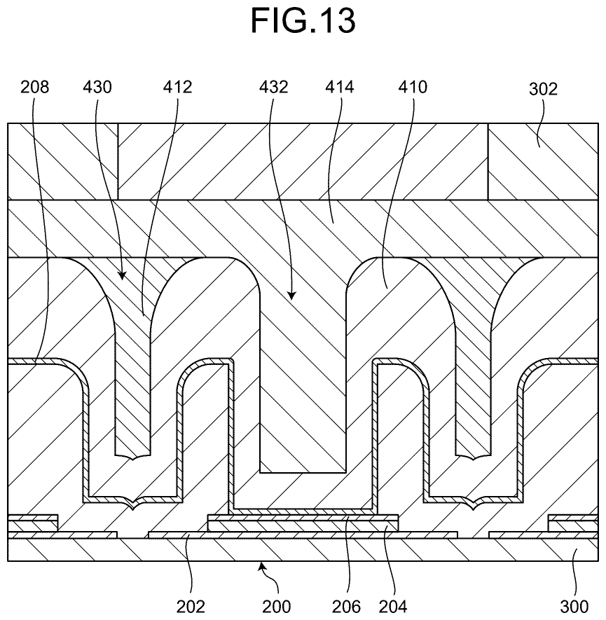

Hereinafter, a modification of the present embodiment will be described with reference to FIGS. 13 and 14. FIGS. 13 and 14 are cross-sectional views for illustrating an example of the configuration of the pixel 20 according to modifications of the present embodiment, and is an enlarged view of a corresponding region of a region surrounded by a broken line in FIG. 3. Specifically, FIGS. 13 and 14 are cross-sectional views when the light emitting element 200 of the subpixel 100 is cut in a direction perpendicular to the plane of the substrate 300.

As illustrated in FIG. 13, in the present modification, the protective film 410 is embedded in the contact hole 432 so as to cover the wiring 208 on the side surface of the contact hole 432 similarly to the present embodiment. Furthermore, in the present modification, the protective film 414 is embedded in the center portion of the contact hole 432 so as to cover the protective film 410. In other words, in the present modification, the wiring 208 on the side surface of the contact hole 432 is covered with a stack of the protective film 410 and the protective film 414.

In the modification with this configuration, it is possible to suppress reflection of light from the light emitting layer 204 at the interface located above the cathode electrode 206, enabling the light from the light emitting layer 204 to be guided upward. As a result, the present modification can improve the upward light extraction efficiency.

As illustrated in FIG. 14, in the present modification, the wiring 208 extends so as to cover the upper surface of the trench 430 in a cross section (cross-sectional view) when cut in a direction perpendicular to the plane of the substrate 300 based on the configuration of the above-described modification of FIG. 13. Since the upper surface of the protective film 412 in the trench 430 is planarized, the present modification makes it possible to form the wiring 208 with a uniform and high-quality film by forming the wiring 208 on the planarized surface. This makes it possible to suppress the occurrence of defects such as disconnection of the wiring 208.

The present modification is not limited to the configuration illustrated in FIGS. 13 and 14, and can be appropriately modified in accordance with desired characteristics and the like.

### 6. Fourth Embodiment

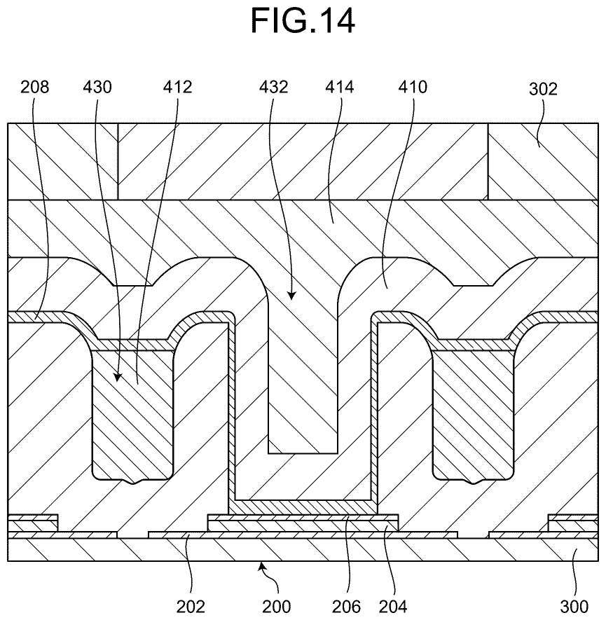

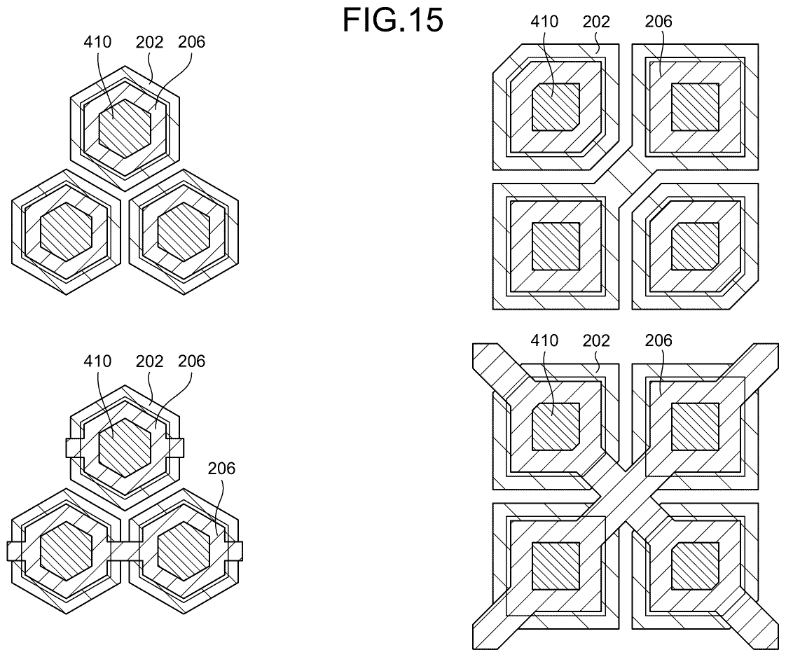

The pixel 20 according to each embodiment of the present disclosure described above can be modified in various manners even in the shape when viewed from above the substrate 300 (in plan view). Accordingly, a modification of the planar configuration of the pixel 20 will be described as a fourth embodiment of the present disclosure with reference to FIGS. 15 and 16. FIGS. 15 and 16 are plan views illustrating an example of the configuration of the pixel 20 according to the present embodiment.

Also in the present embodiment, as described above, the shape of the light emitting element 200 when viewed from above the substrate 300 (in plan view) may be a rectangular shape, or a hexagonal polygonal shape, a circular shape, or an elliptical shape, for example, with no particular limitation.

Furthermore, in the present embodiment, the array of the light emitting elements 200 is not particularly limited, and may be a square array (specifically, the light emitting element 200 is located at a position of each vertex of the square), a delta array (specifically, the light emitting element 200 is located at a position of each vertex of the triangle), or a stripe array.

For example, as illustrated in the upper left drawing of FIG. 15, the light emitting elements 200 having a hexagonal shape may be arranged in a delta array. In this example, each light emitting element 200 is completely divided from each other. In this example, although not illustrated, the protective film 412 is provided between the adjacent light emitting elements 200 so as to surround each light emitting element 200. That is, in the example in the upper left drawing of FIG. 15, the protective film 410 on the cathode electrode 206 is surrounded by the protective film 412. Therefore, in the example in the upper left drawing of FIG. 15, the light beams from the light emitting layer 204 are reflected many times at an interface, being the interface between the protective film 410 and the protective film 412, so as to confined in the protective film 410 to interfere with each other. Therefore, in the example in the upper left drawing of FIG. 15, the protective film 410 functions like a waveguide, and can guide the light from the light emitting layer 204 upward while suppressing spreading of the light. As a result, in the example in the upper left drawing of FIG. 15, it is possible to improve the upward light extraction efficiency of the light emitting device 10.

In addition, for example, as illustrated in the lower left drawing of FIG. 15, the cathode electrode 206 of each light emitting element 200 is connected to a part of the cathode electrode 206 of the light emitting element 200 adjacent in the left-right direction in the drawing, based on the configuration in the upper left drawing of FIG. 15 described above. With this configuration, in the example in the lower left drawing of FIG. 15, the cathode electrodes 206 are partially connected to each other, making it unnecessary to provide the above-described wiring 208. Furthermore, in the example in the lower left drawing of FIG. 15, the electric resistance of the cathode electrode 206 can be reduced.

Furthermore, for example, as illustrated in the upper right drawing of FIG. 15, the light emitting elements 200 having a quadrangular shape may be disposed in a square array. In this example, in each light emitting element 200, a part of the anode electrodes 202 of the light emitting elements 200 disposed at the upper right and the lower left is connected to each other, while the anode electrodes 202 of the light emitting elements 200 disposed at the lower right and the upper left are not connected to each other. In this example, although not illustrated, the protective film 412 is provided between the adjacent light emitting elements 200 so as to surround each light emitting element 200. That is, also in the example in the upper right drawing of FIG. 15, the protective film 410 on the cathode electrode 206 is surrounded by the protective film 412. Therefore, in the example in the upper right drawing of FIG. 15, the light beams from the light emitting layer 204 are reflected many times at an interface, being the interface between the protective film 410 and the protective film 412, so as to confined in the protective film 410 to interfere with each other. Therefore, in the example in the upper right drawing of FIG. 15, the protective film 410 functions like a waveguide, and can guide the light from the light emitting layer 204 upward while suppressing spreading of the light. As a result, in the example in the upper right drawing of FIG. 15, it is possible to improve the upward light extraction efficiency of the light emitting device 10.

Furthermore, for example, as illustrated in the lower right drawing of FIG. 15, the cathode electrode 206 of each of the light emitting elements 200 is connected to a part of the cathode electrode 206 of the light emitting element 200 adjacent to each other in the horizontal and vertical directions in FIG. 15 based on the configuration in the upper right drawing of FIG. described above. With this configuration, also in the example in the lower right drawing of FIG. 15, the cathode electrodes 206 are partially connected to each other, making it unnecessary to provide the above-described wiring 208. Furthermore, also in the example in the lower right drawing of FIG. 15, the electric resistance of the cathode electrode 206 can be reduced.

Furthermore, for example, the example illustrated in the upper left drawing of FIG. 16 is an example in which the contact hole 432 for the wiring 208 is provided based on the configuration in the upper left drawing of FIG. 15 described above. In this example, when viewed from above the substrate 300 (in plan view), the shape of the contact hole 432 provided in the protective film 410 on the cathode electrode 206 of the light emitting element 200 is a cross-shaped line pattern. Furthermore, in this example, although not illustrated, the wiring 208 and the protective film 410 are provided so as to cover the side surface of the contact hole 432. Furthermore, the protective film 412 is embedded in the contact hole 432. In addition, in this example, similarly to the above-described example, the protective film 412 is provided between the adjacent light emitting elements 200 so as to surround each light emitting element 200.

With this configuration in the example in the upper left drawing of FIG. 16, the light from the light emitting layer 204 is reflected at the interface between the protective film 412 and the protective film 410 embedded in the contact hole 432, making it possible to guide the light efficiently into the protective film 410. As a result, in the example in the upper left drawing of FIG. 16, it is possible to improve the upward light extraction efficiency. Furthermore, with such a shape in this example, a gas intrusion path is generated in the manufacturing process, making it possible to form the film efficiently so as to fill the contact hole 432.

Furthermore, for example, the example illustrated in the lower left drawing of FIG. 16 is also an example in which the contact hole 432 for the wiring 208 is provided based on the configuration in the upper left drawing of FIG. 15 described above. In this example, when viewed from above the substrate 300 (in plan view), the contact hole 432 is provided in the protective film 410 on the cathode electrode 206 of the light emitting element 200, and four contact holes 432 are provided for one light emitting element 200. Also in this example, although not illustrated, the wiring 208 and the protective film 410 are provided so as to cover the side surface of the contact hole 432. Furthermore, also in this example, the protective film 412 is embedded in the contact hole 432. In addition, in this example, similarly to the above-described example, the protective film 412 is provided between the adjacent light emitting elements 200 so as to surround each light emitting element 200.

With this configuration also in the example in the lower left drawing of FIG. 16, the light from the light emitting layer 204 is reflected at the interface between the protective film 412 and the protective film 410 embedded in the contact hole 432, making it possible to guide the light efficiently into the protective film 410. As a result, also in the example in the lower left drawing of FIG. 16, it is possible to improve the upward light extraction efficiency. Furthermore, in this example, the electrical connection to one light emitting element 200 is made via the wiring 208 of the four contact holes 432. Therefore, even when the wiring 208 of one contact hole 432 is disconnected, for example, the cathode electrode 206 is electrically connected at another position, making it possible to maintain the electrical connection in the cathode electrode 206 of the light emitting element 200. In other words, it is possible, with this example, to avoid occurrence of a defect due to disconnection.

Furthermore, for example, the example illustrated in the upper right drawing of FIG. 16 is an example in which the contact hole 432 for the wiring 208 is provided based on the configuration in the upper left drawing of FIG. 15 described above. In this example, the contact hole 432 is provided in the protective film 410 on the cathode electrode 206 of the light emitting element 200, and the wiring 208 (not illustrated) and the protective film 410 are provided in the contact hole 432 so as to cover the side surface of the contact hole 432. Furthermore, the protective film 412 is embedded in the contact hole 432. In addition, in this example, similarly to the above-described example, the protective film 412 is provided between the adjacent light emitting elements 200 so as to surround each light emitting element 200.

With this configuration in the example in the upper right drawing of FIG. 16, the light from the light emitting layer 204 is reflected at the interface between the protective film 412 and the protective film 410 embedded in the contact hole 432, making it possible to guide the light efficiently into the protective film 410. As a result, in the example in the upper right drawing of FIG. 16, it is possible to improve the upward light extraction efficiency.

Furthermore, for example, in the example illustrated in the lower right drawing of FIG. 16, the size (width) of the protective film 410 on the cathode electrode 206 is varied for each wavelength of light emitted from the light emitting layer 204 of the light emitting element 200 based on the above-described configuration in the upper left drawing of FIG. 15. In this example, not only the size (width) but also the shape and the like of the protective film 410 on the cathode electrode 206 may be varied. In this example, by varying the size and shape of the protective film 410 that functions like a waveguide in accordance with the wavelength of light, it is possible to optimize the light condensing function of the protective film 410.

Furthermore, in this example, by varying the size and shape of the protective film 410 on the cathode electrode 206 in accordance not only with the wavelength but also with the position in the display region of the light emitting device 10, the direction of guiding light may be adjusted in accordance with the position in the display region of the light emitting device 10.

The present embodiment is not limited to the configuration illustrated in FIGS. 15 and 16, and can be appropriately modified in accordance with desired characteristics and the like.

### 7. Fifth Embodiment

### 7.1 Manufacturing Method

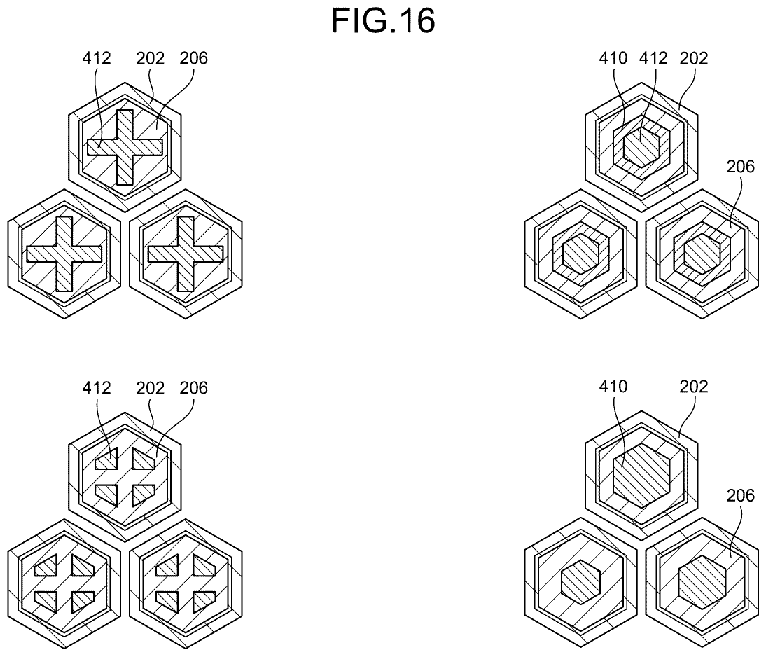

Next, an example of a method of manufacturing the pixel 20 of the third embodiment of the present disclosure will be described with reference to FIGS. 17A and 17B. FIGS. 17A and 17B are explanatory diagrams for illustrating the method of manufacturing the pixel 20 of the present embodiment, and correspond to the cross-sectional view of FIG. 12.

First, as illustrated in the upper drawing of FIG. 17A, the patterned anode electrode 202 is formed on the substrate 300, and the light emitting layer 204 and the cathode electrode 206 are sequentially stacked on the anode electrode 202. Furthermore, a protective film 410 is stacked on the cathode electrode 206. Thereafter, the light emitting layer 204, the cathode electrode 206, and the protective film 410 are patterned by a technique such as photolithography, and the protective film 410 is stacked again. Next, as illustrated in the middle drawing of FIG. 17A, a mask having a predetermined pattern is formed on the protective film 410 by photolithography, etching is performed according to the pattern of the mask to form, on the protective film 410, the contact hole 432 that exposes the upper surface of the cathode electrode 206. Furthermore, as illustrated in the lower drawing of FIG. 17A, the wiring 208 is formed along a part of the side surface of the contact hole 432 and the upper surface of the protective film 410, and the protective film 410 is stacked on the wiring 208.

Next, as illustrated in the upper drawing of FIG. 17B, the protective film 412 is formed on the protective film 410. Subsequently, as illustrated in the middle drawing of FIG. 17B, the upper surface of the protective film 412 is planarized by a technique such as CMP. Furthermore, as illustrated in the lower drawing of FIG. 17B, the protective film 414 is formed on the protective film 412.

### 7.2 Modification

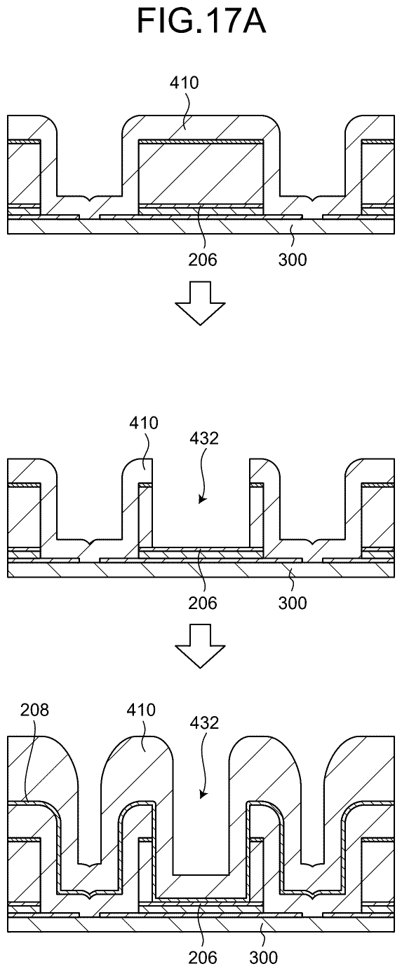

Next, a method of manufacturing the pixel 20 according to a modification of the third embodiment of the present disclosure will be described with reference to FIGS. 18A to 18C. FIGS. 18A to 18C are explanatory diagrams for illustrating the method of manufacturing the pixel 20 of the modification of the present embodiment, and correspond to the cross-sectional view of FIG. 13.

First, as illustrated in the upper drawing of FIG. 18A, the patterned anode electrode 202 is formed on the substrate 300, and the light emitting layer 204 and the cathode electrode 206 are sequentially stacked on the anode electrode 202. Furthermore, a mask formed of the same material as that of the protective film 410 is stacked on the cathode electrode 206, and then the protective film 410 is stacked over the entire range. Next, as illustrated in the middle drawing of FIG. 18A, the protective film 412 is formed on the protective film 410. Furthermore, as illustrated in the lower drawing of FIG. 18A, the upper surface of the protective film 410 is planarized by a technique such as CMP such that a part of the protective film 412 on the light emitting element 200 is exposed from the outermost surface.

Next, as illustrated in the upper drawing of FIG. 18B, the protective film 410 is further formed on the protective film 412. Furthermore, as illustrated in the lower drawing of FIG. 18B, the contact hole 432 is formed in the protective film 410 so as to expose the upper surface of the cathode electrode 206.

Furthermore, as illustrated in the upper drawing of FIG. 18C, the wiring 208 is formed along a part of the side surface of the contact hole 432 and the upper surface of the protective film 410, and the protective film 410 is stacked on the wiring 208. Next, as illustrated in the lower drawing of FIG. 18C, the protective film 414 is formed on the protective film 410.

The manufacturing method described here is an example, and can be appropriately changed in the present embodiment and its modification.

### 8. Sixth Embodiment

### 8.1 Detailed Configuration

In the embodiments of the present disclosure described above, the light from the light emitting layer 204 is reflected at the interface between the protective film 410 and the protective film 412 in the trench 430 provided in the protective film 410, and the light from the light emitting layer 204 can be guided toward the upper side of the light emitting element 200 while being suppressed from spreading. As a result, according to these embodiments, it is possible to improve the upward light extraction efficiency in the light emitting device 10. Furthermore, according to these embodiments, the light is suppressed from being guided to the color filters 302 of the adjacent subpixels 100, making it possible to suppress occurrence of color mixing. However, according to the study of the present inventors, these embodiments have a limit in improving color purity.

Specifically, in these embodiments, when white light is emitted from the light emitting layer 204, the blue, red, and green color filters 302 are provided above the light emitting element 200, so that the color of the light emitted from the subpixel 100 is set to a desired color. However, in the configuration using such a color filter 302, the color purity is lower compared with a method of emitting light of a desired color from the light emitting layer 204 itself.

In view of this, the present inventors have conceived a notion of increasing color purity by embedding the color filter 302 in the contact hole 432 provided on the light emitting element 200 in the same configuration as the subpixel 100 according to the third embodiment, and have created a sixth embodiment of the present disclosure described below. Hereinafter, details of the sixth embodiment of the present disclosure created by the present inventors will be sequentially described. The following description will omit description overlapping the description of each embodiment described above.

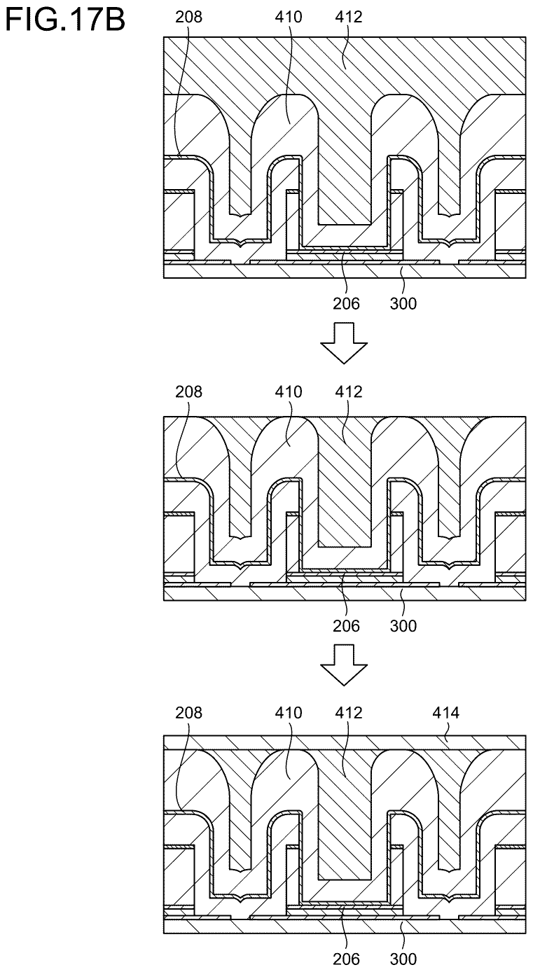

First, the sixth embodiment of the present disclosure will be described with reference to FIG. 19. FIG. 19 is a cross-sectional view for illustrating an example of the configuration of the pixel 20 according to the present embodiment, and specifically, is a cross-sectional view when the light emitting element 200 of the subpixel 100 is cut in a direction perpendicular to the plane of the substrate 300. Similarly to the above third embodiment, the present embodiment is an embodiment further including wiring (second wiring) 208 electrically connecting the cathode electrodes 206 of adjacent light emitting elements 200 to each other.

Specifically, as illustrated in FIG. 19, in the present embodiment, the protective film 410 has a contact hole 432 exposing a part (specifically, the central portion) of the upper surface of the cathode electrode 206, similarly to the third embodiment. Furthermore, the wiring 208 is provided so as to cover at least a part of the side surface of the contact hole 432. The wiring 208 is electrically connected to the upper surface of the cathode electrode 206 exposed from the contact hole 432. In addition, in a cross section (cross-sectional view) when cut in a direction perpendicular to the plane of the substrate 300, the wiring 208 extends so as to pass below the trench 430 and further extends so as to cover the side surface of the contact hole 432 of the adjacent light emitting element 200. This makes it possible for the wiring 208 to electrically connect the cathode electrodes 206 of the adjacent light emitting elements 200 to each other.

In the present embodiment, as illustrated in FIG. 19, similarly to the third embodiment, the protective film 410 is embedded in the contact hole 432 so as to cover the wiring 208 on the side surface of the contact hole 432 and a part of the upper surface of the cathode electrode 206. In the present embodiment, unlike the third embodiment, the contact hole 432 is provided with a color filter (first color conversion film) 302a so as to cover the protective film 410 on the side surface of the contact hole 432 and to fill the contact hole 432. In the present embodiment, as illustrated in FIG. 19, the color filter 302a is provided so as to fill the entire contact hole 432 and so as to protrude from the contact hole 432. In other words, the subpixel 100 according to the present embodiment includes: the color filter (first color conversion film) 302a embedded in the contact hole 432; and a color filter (second color conversion film) 302b stacked on the color filter 302a embedded in the contact hole 432.

In the present embodiment, the color filters 302a and 302b may be color filters that selectively transmit light having red, blue, and green, for example, or color filters that transmit light having colors other than these colors. In the present embodiment, the color filter (first color conversion film) 302a embedded in the contact hole 432 and the color filter (second color conversion film) 302b stacked on the color filter 302a embedded in the contact hole 432 may be color filters that transmit light of the same color or color filters that transmit light of different colors.

In the present embodiment, as illustrated in FIG. 19, the lower surface of the stacked color filter 302b is in contact with the protective film (low refractive index film) 412 embedded in the trench (first trench) 430. In the present embodiment, the color filters 302a and 302b each has a refractive index higher than the refractive index of the protective film 412. Therefore, the light from the light emitting layer 204 is reflected at the interface between the color filter 302b and the protective film 412, and the light can be guided toward the upper side of the light emitting element 200.

More specifically, for example, the color filters 302a and 302b can be formed of a material having a refractive index of about 1.6 to 1.7 similarly to the above-described embodiments, and specifically, for example, can be formed of a material in which a pigment or a dye is dispersed in a transparent binder such as silicone.

As described above, the present embodiment allows more light out of the light from the light emitting layer 204 to pass through the color filter 302a embedded in the contact hole 432, making it possible to improve color purity.

The present embodiment is not limited to the configuration illustrated in FIG. 19, and can be appropriately modified in accordance with desired characteristics and the like.

Furthermore, in the present embodiment, the planar configuration of the subpixel 100 can be formed as in the fourth embodiment described with reference to FIGS. 15 and 16. That is, also in the present embodiment, the shape of the light emitting element 200 when viewed from above the substrate 300 (in plan view) may be a rectangular shape, or a hexagonal polygonal shape, a circular shape, or an elliptical shape, for example, with no particular limitation. Also in the present embodiment, the array of the light emitting elements 200 may be a square array, a delta array, or a stripe array, with no particular limitation. Furthermore, in the present embodiment, the shape, size, array layout, and the like of the light emitting element 200 may be varied in accordance with the position in the display region of the light emitting device 10 and the color of the emitted light.

### 8.2 Modification

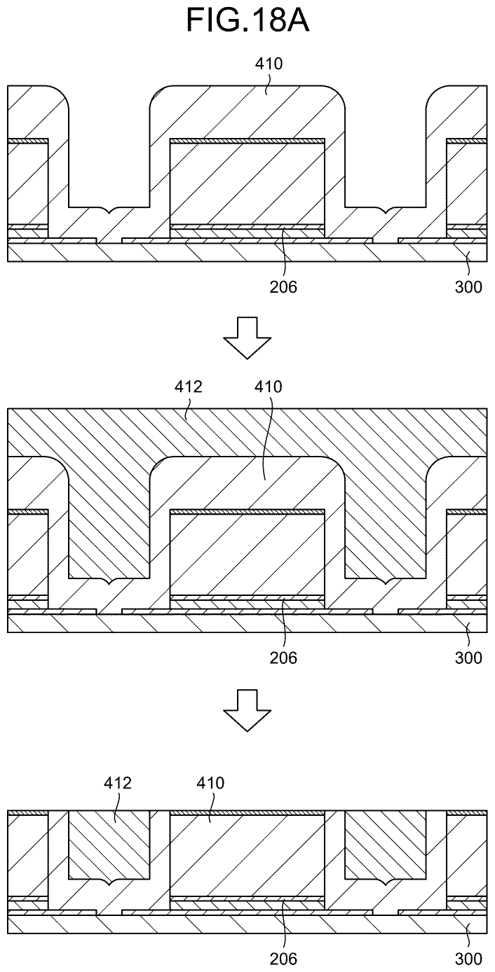

Hereinafter, the modification of the present embodiment will be described with reference to FIGS. 20 to 26. FIGS. 20 to 26 are cross-sectional views for illustrating an example of the configuration of the pixel 20 according to first to seventh modifications of the present embodiment, and specifically, is a cross-sectional view when the light emitting element 200 of the subpixel 100 is cut in a direction perpendicular to the plane of the substrate 300.

### First Modification

In a first modification, as illustrated in FIG. 20, the protective film 412 may protrude from the trench 430 so as to penetrate a part of the color filter 302b in the film thickness direction of the color filter 302b. Accordingly, in the present modification, the stacked color filter 302b is in contact with the protective film 412 embedded in the trench 430. In the present modification with this configuration, the light from the light emitting layer 204 is reflected at the interface between the protective film 412 and the color filter 302b, making it possible to guide the light from the light emitting layer 204 toward the upper side of the light emitting element 200. As a result, according to the present modification, it is possible to improve the upward light extraction efficiency in the light emitting device 10.

### Second Modification

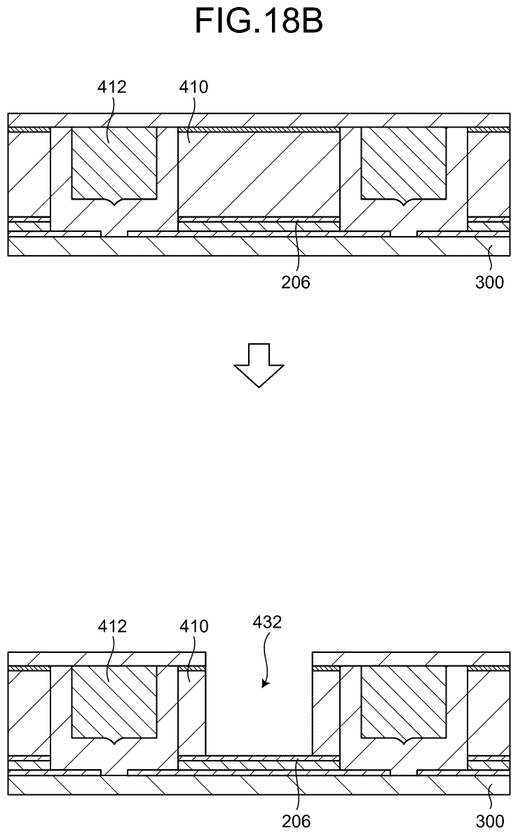

In a second modification, as illustrated in FIG. 21, there is provided a protective film (third protective film) 416 between the color filter (first color conversion film) 302a embedded in the contact hole 432 and a color filter (third color conversion film) 302c stacked on the color filter 302a. In other words, the protective film 416 is provided on the color filter 302a, and the color filter 302c is provided on the protective film 416.

In the present modification, the protective film 416 has a refractive index higher than the refractive index of the protective film 412. Furthermore, the protective film 416 preferably is to be equivalent, in refractive index, to the protective film 410. Accordingly, in the present modification, the light transmitted through the protective film 412 is guided to the protective film 416, making it possible to guide the light toward the upper side of the light emitting element 200. As a result, according to the present modification, it is possible to improve the upward light extraction efficiency in the light emitting device 10.

### Third Modification

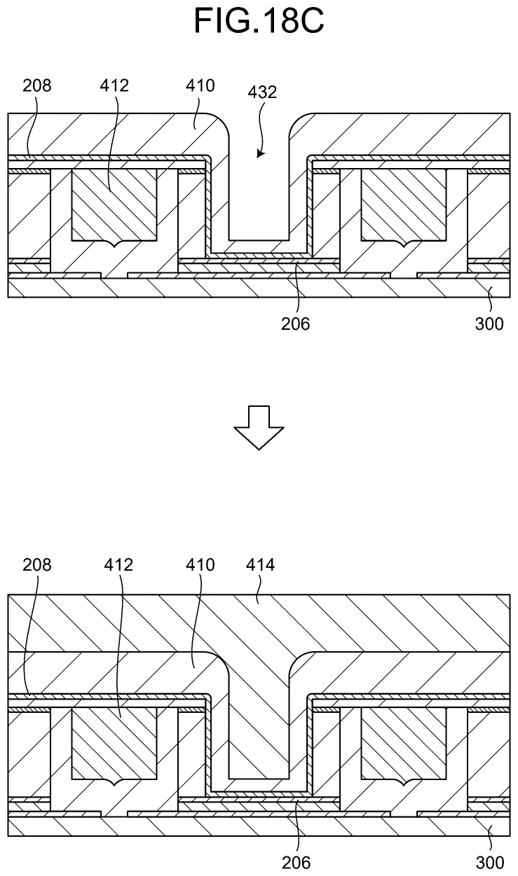

In the third modification, as illustrated in FIG. 22, a protective film (fourth protective film) 418 is embedded in the bottom portion of the contact hole 432, and the color filter (first color conversion film) 302a is further stacked on the protective film 418. In other words, in the present modification, unlike the present embodiment, the color filter 302a is embedded in only a part of the contact hole 432.

Furthermore, in the present modification, the protective film 418 has a refractive index higher than the refractive index of the protective film 412 and has the refractive index different from the refractive index of the color filter 302. The protective film 418 is formed of a material with a high refractive index, and is preferably formed of a material having a refractive index equivalent to or lower than the refractive index of the protective film 410.

In the present modification, the protective film 418 is embedded in the bottom portion of the contact hole 432 to enable thinning of the color filter 302a in the contact hole 432, making it possible to suppress absorption of light by the color filter 302a, leading to further improvement of light extraction efficiency.

### Fourth to Sixth Modifications

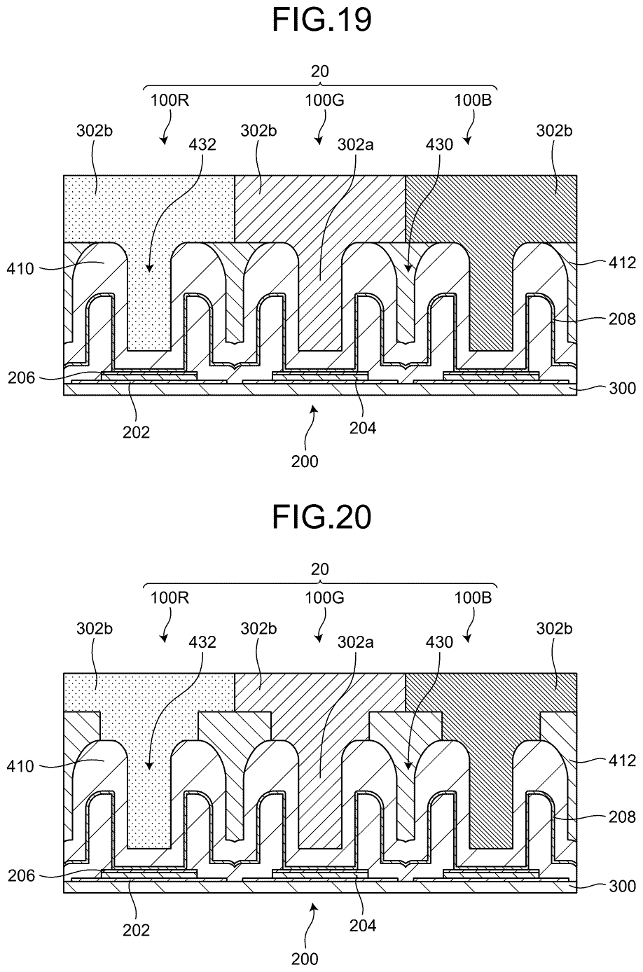

FIGS. 23 to 25 are cross-sectional views for illustrating an example of the configuration of the pixel 20 according to third to sixth modifications of the present embodiment. In these modifications, the color filter (first color conversion film) 302a is embedded in the contact hole 432 only in a part of the light emitting elements 200 among the plurality of light emitting elements 200 included in the light emitting device 10.

For example, in the fourth modification illustrated in FIG. 23, the color filter (first color conversion film) 302a is embedded in the contact hole 432 in the subpixel 100R that emits red light. Furthermore, in the fourth modification, the protective film 414 is embedded in the contact hole 432 in the subpixels 100G and 100B that emit green and blue light, respectively. The protective film 414 is formed of a material having a high refractive index. Specifically, the protective film 414 is formed of a material having a refractive index higher than the refractive index of the protective film 412 and having a refractive index equivalent to or lower than the refractive index of the protective film 410. In other words, in the present modification, the subpixel 100R has the configuration of the sixth embodiment, while the subpixels 100G and 100B have the configuration of the third embodiment.

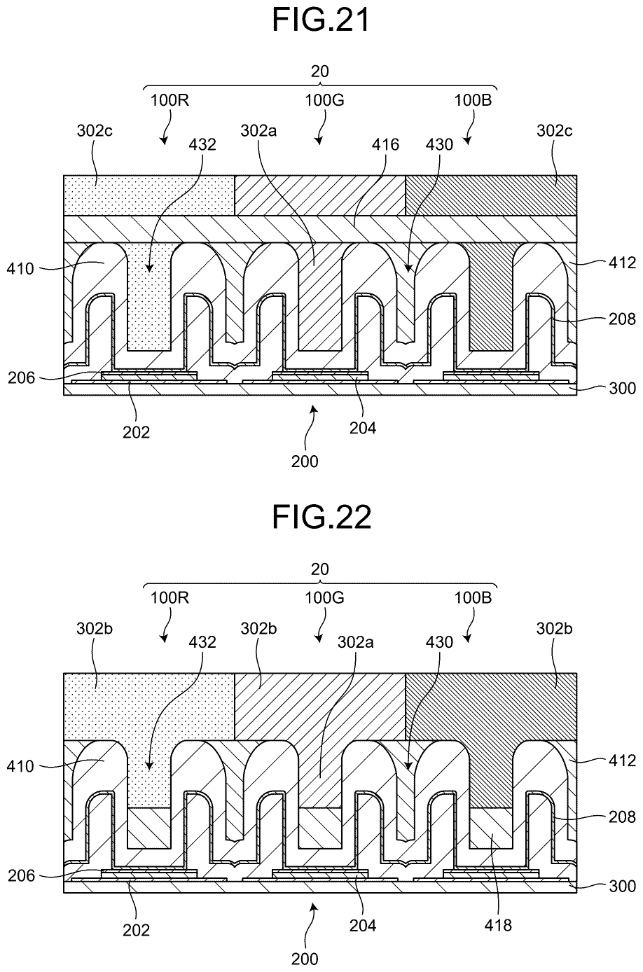

For example, in the fifth modification illustrated in FIG. 24, the color filter (first color conversion film) 302a is embedded in the contact hole 432 in the subpixels 100R and 100G that emit red light and green light, respectively. On the other hand, the protective film 414 is embedded in the contact hole 432 in the subpixel 100G that emits blue light. In other words, in the present modification, the subpixels 100R and 100G have the configuration of the sixth embodiment, and the subpixel 100B has the configuration of the third embodiment.

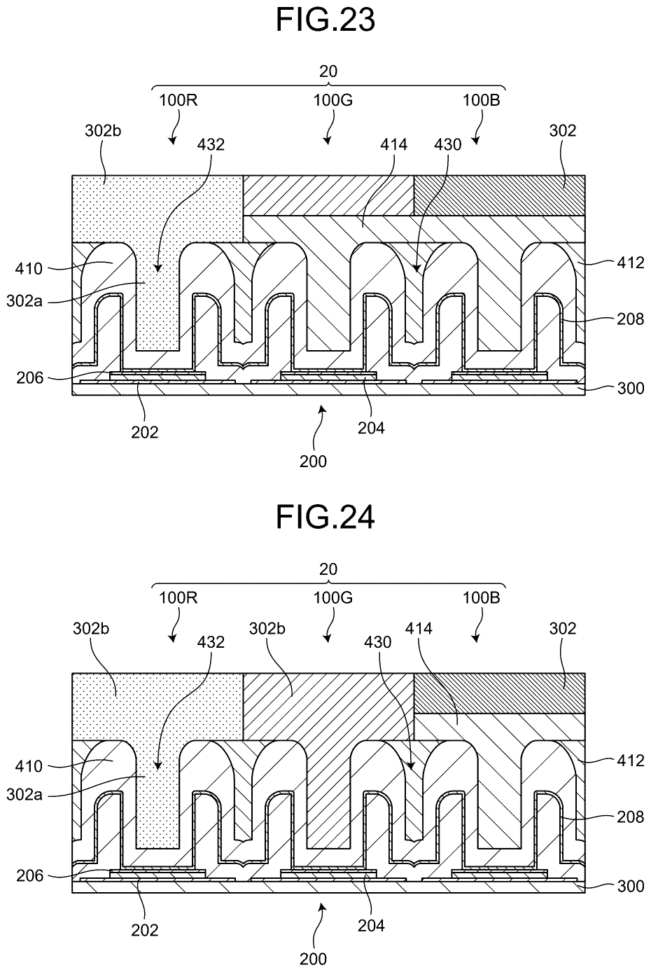

For example, in the sixth modification illustrated in FIG. 25, the color filter (first color conversion film) 302a is embedded in the contact hole 432 in the subpixels 100R, 100G, and 100B that emit red light, green light, and blue light, respectively. Furthermore, the protective film 414 is embedded in the contact hole 432 in a subpixels 100N that emit light having a color other than the red, green, and blue. In other words, in the present modification, the subpixels 100R, 100G, and 100B have the configuration of the sixth embodiment, and the subpixel 100N has the configuration of the third embodiment.

In the fourth modification to the sixth modification, the color of the light emitted from the subpixel 100 having the contact hole 432 in which the color filter 302a is embedded can be selected in accordance with desired characteristics. For example, in the above-described modification, the subpixel 100 having the contact hole 432 in which the color filter 302a is embedded and the subpixel 100 having the contact hole 432 in which the color filter 302a is not embedded may emit light of mutually different colors. Furthermore, in the above-described modification, the configuration of the subpixel 100 having the contact hole 432 in which the color filter 302a is embedded is not limited to the configuration illustrated in FIGS. 23 to 25, and may be the configuration illustrated in FIGS. 22 and 23.

### Seventh Modification

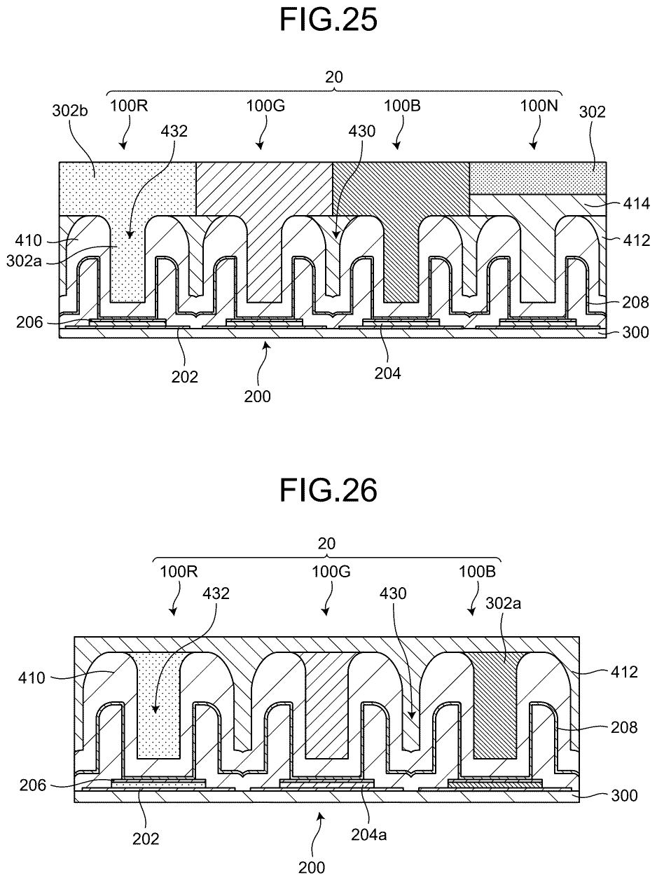

In a seventh modification, as illustrated in FIG. 26, the subpixel 100 includes only the color filter 302a embedded in the contact hole 432, with no color filter 302b stacked on the color filter 302a embedded in the contact hole 432. Furthermore, in the present modification, the light emitting element 200 preferably has the light emitting layer 204a that emits light having a desired color such as red light, green light, or blue light. With this configuration, even in a case where the color filters 302b are not stacked, it is possible to avoid a decrease in color purity. Furthermore, in the present modification, the protective film 412 may be stacked on the color filter 302a embedded in the contact hole 432, and an on-chip lens (not illustrated) may be stacked on the protective film 412.

The present modification, in which the color filter 302b is not stacked, enables thinning of the entire color filter 302, making it possible to suppress light absorption by the color filter 302, leading to further improvement in the light extraction efficiency. Furthermore, the present modification enables reduction of the distance between the light emitting layer 204a and the on-chip lens, making it possible to allow most of the light traveling in an oblique direction from the upper surface of the light emitting layer 204a to be incident on the on-chip lens, leading to improvement in the upward light extraction efficiency.

### 8.3 Manufacturing Method

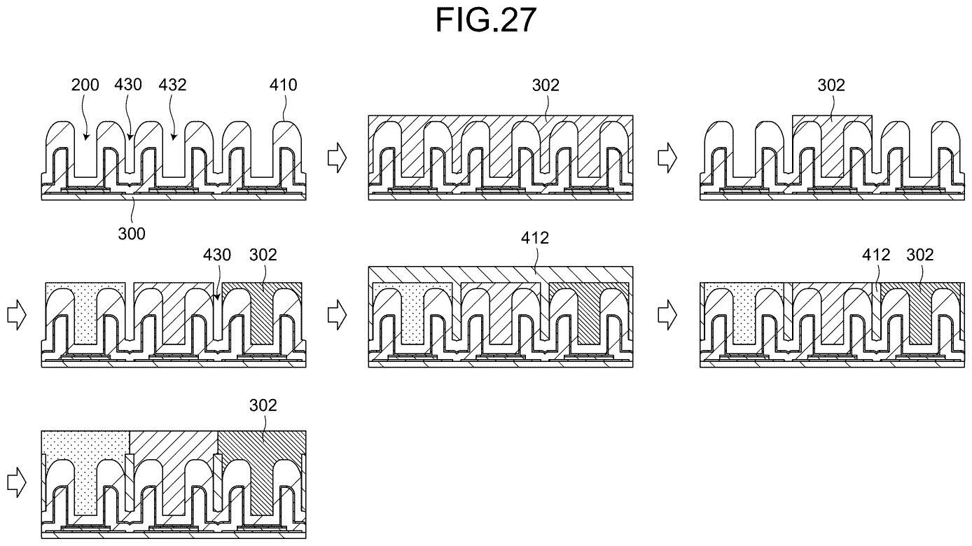

Next, a method of manufacturing the pixel 20 according to the sixth embodiment of the present disclosure will be described with reference to FIG. 27. FIG. 27 is an explanatory diagram for illustrating the method of manufacturing the pixel 20 of the present embodiment, and correspond to the cross-sectional view of FIG. 19.

First, as illustrated in the upper left drawing of FIG. 27, the anode electrode 202, the light emitting layer 204, the cathode electrode 206, and the protective film 410 are sequentially stacked on the substrate 300 to form the light emitting element 200. Furthermore, the trench 430 for separating the light emitting elements 200 and the contact hole 432 for exposing the upper surface of the cathode electrode 206 are formed in the protective film 410. Furthermore, the wiring 208 is formed along a part of the side surfaces of the trench 430 and the contact hole 432 and along the upper surface of the protective film 410, and the protective film 410 is stacked on the wiring 208.

Next, as illustrated in the upper center drawing of FIG. 27, the color filter 302 is applied so as to fill the trench 430 and the contact hole 432. Next, as illustrated in the upper right drawing of FIG. 27, the color filter 302 is left at a desired position using a mask or the like, and the color filter 302 applied at other positions is removed. By repeating this for the number of types of the color filters 302, it is possible to obtain a form as illustrated on the middle left drawing of FIG. 27.

Next, as illustrated in the middle center of FIG. 27, the protective film 412 is formed on the color filter 302 and the protective film 410. Subsequently, as illustrated on the right middle drawing of FIG. 27, the upper surface of the protective film 412 is planarized by a technique such as CMP. Furthermore, as illustrated in the lower drawing of FIG. 27, the color filter 302 is further stacked on the protective film 412.

The manufacturing method described here is an example, and can be appropriately changed in the present embodiment and its modification.

### 9. Seventh Embodiment

### 9.1 Detailed Configuration

In the third embodiment of the present disclosure, there is provided the contact hole 432 that exposes the central portion of the upper surface of the cathode electrode 206, and the wiring 208 is formed so as to cover at least a part of the side surface of the contact hole 432. In the third embodiment, the cathode electrodes 206 of the adjacent light emitting elements 200 are electrically connected to each other by the wiring 208 formed in this manner. In the third embodiment, the protective film 410 is embedded in the contact hole 432 so as to cover the wiring 208 on the side surface of the contact hole 432, and the protective film 412 is embedded in the central portion of the contact hole 432 so as to cover the protective film 410.

That is, in the third embodiment, since the protective film 412 formed of a low refractive index film is formed above the light emitting element 200, the light from the light emitting layer 204 is reflected at the interface between the protective film 410 and the protective film 412 in the contact hole 432, making it difficult to guide most of the light toward the upper side of the light emitting element 200. In addition, in the third embodiment, when the protective films 410 and 412 are formed in the contact hole 432, the film forming rate is low, making it difficult to form the protective films 410 and 412 so as to completely cover the side surface and the bottom surface of the contact hole 432.

In view of this, the present inventors have conceived of exposing the outer periphery of the upper surface of the cathode electrode 206 and providing wiring (third wiring) electrically connected to at least a part of the outer periphery. This configuration makes it possible to electrically connect the cathode electrodes 206 of the adjacent light emitting elements 200 to each other by the wiring described above without providing the protective film 412 in the contact hole 432 above the light emitting element 200. Hereinafter, details of a seventh embodiment of the present disclosure created by the present inventors will be sequentially described. The following description will omit description overlapping the description of each embodiment described above.

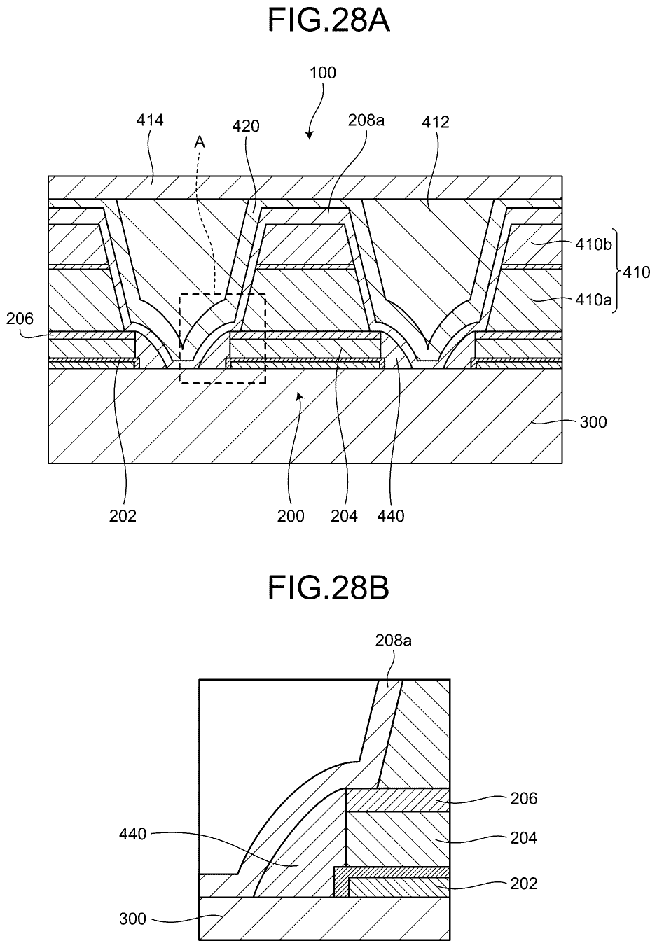

First, the seventh embodiment of the present disclosure will be described with reference to FIGS. 28A and 28B. FIG. 28A is a cross-sectional view for illustrating an example of the configuration of the subpixel 100 according to the present embodiment, and specifically, is a cross-sectional view when the light emitting element 200 of the subpixel 100 is cut in a direction perpendicular to the plane of the substrate 300. FIG. 28B is an enlarged view of region A illustrated in FIG. 28A.

In the present embodiment, as illustrated in FIG. 28A, similarly to the embodiments described above, each light emitting element 200 includes: an anode electrode (first electrode) 202 provided on the substrate 300; a light emitting layer 204 stacked on the anode electrode 202 and configured to emit light; and a cathode electrode (second electrode) 206 stacked on the light emitting layer 204 and transmitting light from the light emitting layer 204. In the present embodiment, the anode electrode 202 may be electrically connected to a wiring layer (not illustrated) provided in the substrate 300. Furthermore, in the present embodiment, the light emitting layer 204 may emit white light, or may emit light such as red light, green light, and blue light.

Furthermore, in the present embodiment, protective films (fifth protective films) 410a and 410b that transmit light from the light emitting layer 204 are sequentially stacked on the cathode electrode 206. These protective films 410a and 410b are formed of a material having a high refractive index, similarly to the protective film 410 in the above-described embodiments. For example, the protective films 410a and 410b are preferably formed of a material having a refractive index of about 1.7 to 2.1 with respect to light having a wavelength of about 450 nm at room temperature, for example. Specifically, the protective films 410a and 410b can be formed of, for example, a nitride film such as silicon nitride (SiN), a transparent conductive film such as indium tin oxide (ITO), indium zinc oxide (IZO), or zinc oxide (ZnO), a transparent organic film, or the like. In other words, the protective films 410a and 410b in the present embodiment correspond to the protective film 410 described above.

In the present embodiment, as illustrated in FIG. 28A, there is provided a sidewall (sidewall portion) 440 so as to cover side surfaces of the anode electrode 202 and the light emitting layer 204. The sidewall 440 can be formed of a material such as silicon oxide (SiO2), silicon nitride (SiN), and silicon oxynitride (SiON), for example,

As illustrated in FIG. 28A, in the present embodiment, wiring (third wiring) 208a is provided so as to cover the upper surface of the protective film 410b, the side surfaces of the protective films 410a and 410b, and the surface of the sidewall 440. That is, the wiring 208a extends from the upper surface of the protective film 410b to the side surfaces of the protective films 410a and 410b, and further extends to the surface of the sidewall 440. Furthermore, the wiring 208a is connected to the wiring 208a of the adjacent light emitting element 200 at a position between the light emitting elements 200. In other words, the wiring 208a is located on the sidewall 440 or the substrate 300 at positions between the adjacent light emitting elements 200.

Furthermore, as illustrated in the enlarged view of FIG. 28B, the outer periphery of the upper surface of the cathode electrode 206 is exposed from the protective film 410a, and the exposed outer periphery is electrically connected to the wiring 208a. In the present embodiment, this configuration allows the cathode electrodes 206 of the adjacent light emitting elements 200 to be electrically connected to each other by the wiring 208a extending between the adjacent light emitting elements 200. The wiring 208a can be formed of, for example, a transparent conductive film such as indium tin oxide (ITO), indium zinc oxide (IZO), or zinc oxide (ZnO). In the present embodiment, the exposed position is not limited to the outer periphery of the upper surface of the cathode electrode 206, and an upper region of the side surface of the cathode electrode 206 may be exposed from the sidewall 440 as well. In this case, the wiring 208a can be electrically connected not only to the outer periphery of the upper surface of the cathode electrode 206 but also to the upper region of the side surface of the cathode electrode 206.

In the present embodiment, as illustrated in FIG. 28A, the wiring 208a, which is provided to cover the upper surface of the protective film 410b, the side surfaces of the protective films 410a and 410b, and the surface of the sidewall 440, is covered with a protective film (sixth protective film) 420. The protective film 420 is provided so as to be continuous through the adjacent light emitting elements 200. The protective film 420 preferably has a refractive index higher than the refractive index of the protective film 412 described below, and more preferably has a refractive index equivalent to the refractive index of the protective films 410a and 410b. In other words, the protective film 420 in the present embodiment corresponds to the protective film 410 described above.

Furthermore, in the present embodiment, as illustrated in FIG. 28A, the protective film 412 formed of a low refractive index film is embedded between the adjacent light emitting elements 200. In other words, in the present embodiment, the protective film 412 is embedded in a portion corresponding to the trench 430 that partitions the adjacent light emitting elements 200 according to the first embodiment of the present disclosure. With this configuration, also in the present embodiment, similarly to the embodiments described above, the light from the light emitting layer 204 is reflected at the interface between the protective film 420 and the protective film 412, making it possible to guide the light toward the upper side of the light emitting element 200.

In the present embodiment, similarly to the second embodiment described above, the protective film 414 is provided so as to cover the upper surfaces of the protective films 412 and 420. In the present embodiment, the protective film 414 preferably has a refractive index higher than the refractive index of the protective film 412, and more preferably has a refractive index equivalent to the refractive index of the protective film 410.

Furthermore, also in the present embodiment, a color filter (not illustrated) and an on-chip lens (not illustrated) may be provided on the protective film 414 for each subpixel 100. Furthermore, in the present embodiment, the color filter may be omitted.

The present embodiment is not limited to the configuration illustrated in FIGS. 28A and 28B, and can be appropriately modified in accordance with desired characteristics and the like.

As described above, the present embodiment exposes the outer periphery of the upper surface of the cathode electrode 206 and provides the wiring 208a electrically connected to at least a part of the outer periphery. This configuration makes it possible, in the present embodiment, to electrically connect the cathode electrodes 206 of the adjacent light emitting elements 200 to each other without providing the contact hole 432 or the protective film 412 above the light emitting element 200. As a result, according to the present embodiment, the light from the light emitting layer 204 is not reflected at the interface between the protective film 410 and the protective film 412, and most of the light can be guided toward the upper side of the light emitting element 200, leading to improvement in the light extraction efficiency.

Furthermore, in the present embodiment, since the protective films 410 and 412 are not to be formed in the contact hole 432, the subpixel 100 having a desired configuration can be easily formed with no necessity to pay attention to the coverage of the protective films 410 and 412. As a result, the present embodiment can improve the reliability of the light emitting device 10.

In addition, the present embodiment can flexibly shape the interface (reflecting surface) of the protective film 412 for guiding light upward as compared with the case where the contact hole 432 is provided, making it possible to further optimize the shape of the reflecting surface as compared with the above-described third embodiment. As a result, according to the present embodiment, most of the light can be guided toward the upper side of the light emitting element 200, leading to further improvement in the light extraction efficiency.

Furthermore, in the present embodiment, the planar configuration of the subpixel 100 can be formed as in the fourth embodiment described with reference to FIGS. 15 and 16. That is, also in the present embodiment, the shape of the light emitting element 200 when viewed from above the substrate 300 (in plan view) may be a rectangular shape, or a hexagonal polygonal shape, a circular shape, or an elliptical shape, for example, with no particular limitation. Also in the present embodiment, the array of the light emitting elements 200 may be a square array, a delta array, or a stripe array, with no particular limitation. Furthermore, in the present embodiment, the shape, size, array layout, and the like of the light emitting element 200 may be varied in accordance with the position in the display region of the light emitting device 10 and the color of the emitted light.

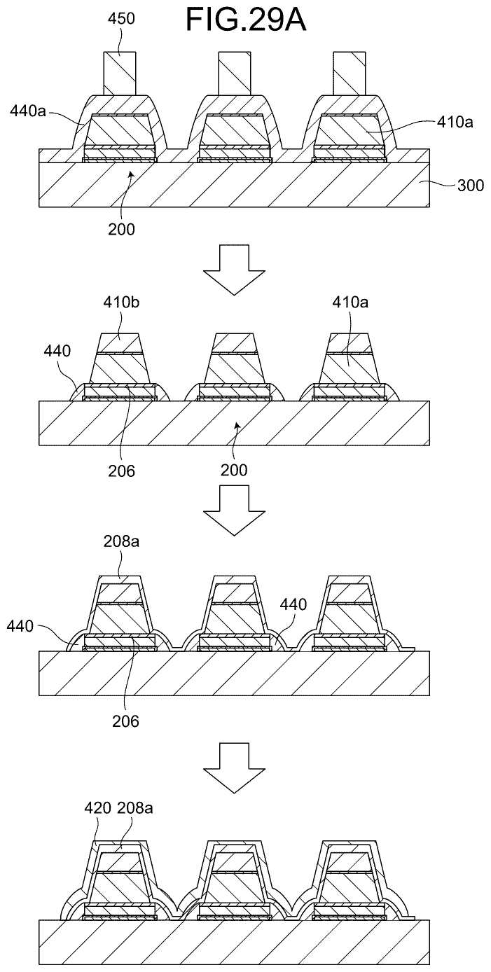

Next, a method of manufacturing the pixel 20 according to the seventh embodiment of the present disclosure will be described with reference to FIGS. 29A and 29B. FIGS. 29A and 29B are explanatory diagrams for illustrating the method of manufacturing the pixel 20 of the present embodiment, and correspond to the cross-sectional view of FIG. 28A.

First, as illustrated in the upper drawing of FIG. 29A, the anode electrode 202, the light emitting layer 204, the cathode electrode 206, and a protective film 410a are sequentially stacked on the substrate 300 to form the light emitting element 200. Furthermore, an insulating film 440a, which is to be a protective film 410b and the sidewall 440, is formed so as to cover the entire light emitting element 200. Next, a resist 450, being a patterned resist, is formed on the light emitting element 200.

Next, as illustrated in the second drawing from the top in FIG. 29A, the insulating film 440a is etched according to the pattern of the resist 450 so as to leave the protective film 410b on the protective film 410a. At this time, the protective film 410a is etched until the outer periphery of the upper surface of the cathode electrode 206 is exposed. Furthermore, at this time, the sidewalls 440 are formed on the side surfaces of the anode electrode 202 and the light emitting layer 204 by a self alignment effect.

Next, as illustrated in the third drawing from the top in FIG. 29A, the wiring 208a a is formed so as to cover the surface of the light emitting element 200 provided with the protective film 410b and the surface of the sidewall 440. At this time, the outer periphery of the upper surface of the cathode electrode 206 exposed from the protective film 410a is electrically connected to the wiring 208a. In addition, since the wiring 208a is provided so as to be continuous between the adjacent light emitting elements 200, the cathode electrodes 206 of the adjacent light emitting elements 200 can be electrically connected to each other. In this manner, in the present embodiment, the protective film 410a is etched so as to expose the outer periphery of the upper surface of the cathode electrode 206, and then the wiring 208a is formed, making it possible to easily form the wiring 208a reliably connected to the outer periphery of the upper surface of the cathode electrode 206.

Furthermore, as illustrated in the lower drawing of FIG. 29A, a protective film 420 is formed so as to cover the wiring 208a.

Next, as illustrated in the upper drawing of FIG. 29B, a protective film 412 is formed so as to fill the space between the light emitting elements 200. Subsequently, as illustrated in the middle drawing of FIG. 29B, the upper surface of the protective film 412 is planarized by a technique such as CMP. Furthermore, as illustrated in the lower drawing of FIG. 29B, the protective film 414 is further stacked on the protective film 412.

The manufacturing method described here is an example, and can be appropriately changed in the present embodiment.

### 9.2 First Modification

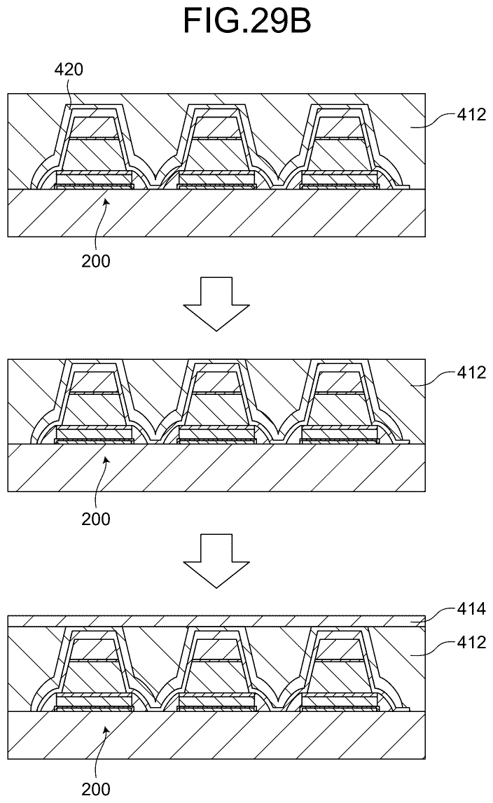

Next, a first modification of the present embodiment will be described with reference to FIG. 30. FIG. 30 is a cross-sectional view for illustrating an example of the configuration of the pixel 20 according to the first modification of the present embodiment, and specifically, is a cross-sectional view when the light emitting element 200 of the subpixel 100 is cut in a direction perpendicular to the plane of the substrate 300.

As illustrated in FIG. 30, also in the present modification, the light emitting element 200 includes the anode electrode 202 provided on the substrate 300, the light emitting layer 204, and the cathode electrode 206. Furthermore, also in the present modification, the protective films 410a and 410b that transmit light from the light emitting layer 204 are sequentially stacked on the cathode electrode 206. Also in the present modification, as illustrated in FIG. 30, there is provided a sidewall 440 so as to cover the side surfaces of the anode electrode 202 and the light emitting layer 204.

Furthermore, in the present modification, unlike the present embodiment, the subpixel 100 includes a contact 212 provided in the substrate 300 located between the adjacent light emitting elements 200 as illustrated in FIG. 30. A part of the upper surface of the contact 212 is exposed from a trench (second trench) 434 provided in the substrate 300. The contact 212 is formed of, for example, a conductive material such as metal, and is electrically connected to the wiring layer (not illustrated) provided in the substrate 300. In the present modification, with the contact 212 provided between the adjacent light emitting elements 200, it is possible to avoid elongated routing of the wiring 208a, making it possible to avoid a decrease in the voltage applied to the cathode electrode 206 due to the resistance value of the wiring 208a.

Furthermore, as illustrated in FIG. 30, in the present modification, the wiring (third wiring) 208a is provided so as to cover the upper surface of the protective film 410b, the side surfaces of the protective films 410a and 410b, the surface of the sidewall 440, the side surface of the trench 434, and the upper surface of the contact 212. That is, the wiring 208a extends from the upper surface of the protective film 410b to the side surfaces of the protective films 410a and 410b, the surface of the sidewall 440, and the side surface of the trench 434, and further extends to the upper surface of the contact 212. In this manner, the wiring 208a is electrically connected to the contact 212. Specifically, between the adjacent light emitting elements 200, the wiring 208a is located below the anode electrode 202 in the film thickness direction of the substrate 300. Furthermore, also in the present modification, the outer periphery of the upper surface of the cathode electrode 206 is exposed from the protective film 410a, and the exposed outer periphery is electrically connected to the wiring 208a. Note that the contact 212, in the present modification, is shared by the light emitting elements 200 at positions sandwiching the contact 212.

Also in the present modification, as illustrated in FIG. 30, the wiring 208a is covered with a protective film 420. Also in the present modification, the protective film 412 formed of a low refractive index film is embedded between the adjacent light emitting elements 200. Furthermore, also in the present modification, the protective film 414 is provided so as to cover the upper surfaces of the protective films 412 and 420.

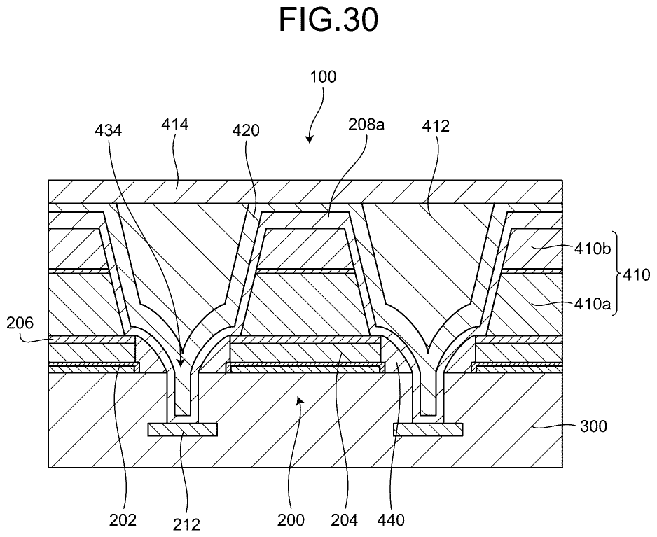

Next, a method of manufacturing the pixel 20 according to the first modification of the seventh embodiment of the present disclosure will be described with reference to FIGS. 31A and 31B. FIGS. 31A and 31B are explanatory diagrams for illustrating the method of manufacturing the pixel 20 of the present embodiment, and correspond to the cross-sectional view of FIG. 30.

First, as illustrated in the upper drawing of FIG. 30A, the anode electrode 202, the light emitting layer 204, the cathode electrode 206, and the protective film 410a are sequentially stacked on the substrate 300 to form the light emitting element 200. Furthermore, an insulating film to be the protective film 410b and the sidewall 440 is formed so as to cover the entire light emitting element 200, and the insulating film is etched to leave the protective film 410b on the protective film 410a. At this time, the protective film 410a is etched until the outer periphery of the upper surface of the cathode electrode 206 is exposed. Furthermore, at this time, the sidewalls 440 are formed on the side surfaces of the anode electrode 202 and the light emitting layer 204 by a self alignment effect. In addition, in the present modification, the trench 434 is formed between the adjacent light emitting elements 200 so as to expose a part of the upper surface of the contact 212 provided in the substrate 300.

Next, as illustrated in the middle drawing of FIG. 30A, the wiring 208a is formed so as to cover the surface of the light emitting element 200 provided with the protective film 410b, the surface of the sidewall 440, and the side surface of the trench 434. Furthermore, as illustrated in the lower drawing of FIG. 30A, the protective film 420 is formed so as to cover the wiring 208a.

Next, as illustrated in the upper drawing of FIG. 30B, the protective film 412 is formed so as to fill the space between the light emitting elements 200. Subsequently, as illustrated in the middle drawing of FIG. 30B, the upper surface of the protective film 412 is planarized by a technique such as CMP. Furthermore, as illustrated in the lower drawing of FIG. 30B, the protective film 414 is further stacked on the protective film 412.

The manufacturing method described here is an example, and can be appropriately changed in the present modification.

### 9.3 Second Modification

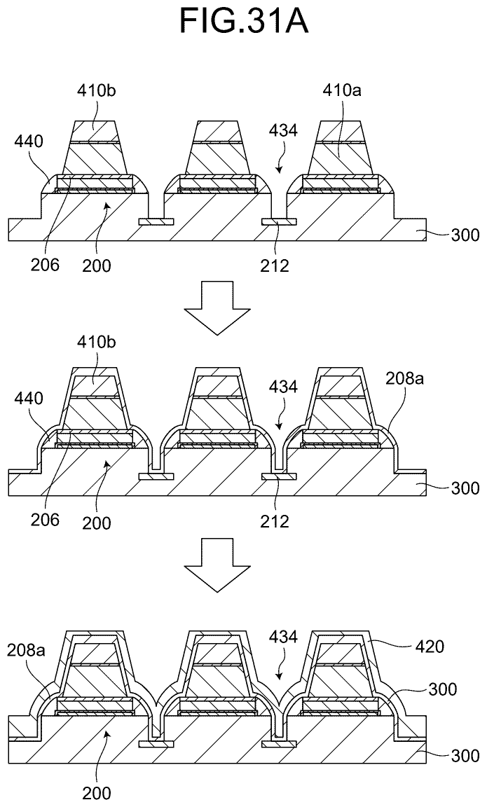

Next, a second modification of the present embodiment will be described with reference to FIG. 32. FIG. 32 is a cross-sectional view for illustrating an example of the configuration of the pixel 20 according to the second modification of the present embodiment, and specifically, is a cross-sectional view when the light emitting element 200 of the subpixel 100 is cut in a direction perpendicular to the plane of the substrate 300.

As illustrated in FIG. 32, also in the present modification, the light emitting element 200 includes the anode electrode 202 provided on the substrate 300, the light emitting layer 204, and the cathode electrode 206. Furthermore, also in the present modification, the protective films 410a and 410b that transmit light from the light emitting layer 204 are sequentially stacked on the cathode electrode 206. In the present modification, as illustrated in FIG. 32, unlike the present embodiment and the first modification, the sidewall 440 is provided so as to cover the side surfaces of the anode electrode 202 and the light emitting layer 204 and to fill the space between the adjacent light emitting elements 200. In FIG. 32, the sidewall 440 has a cross sectional shape of two semicircles arranged side by side, but the present modification is not limited to such a shape.

Furthermore, as illustrated in FIG. 32, also in the present modification, the wiring (third wiring) 208a is provided so as to cover the upper surface of the protective film 410b, the side surfaces of the protective films 410a and 410b, and the surface of the sidewall 440. That is, the wiring 208a extends from the upper surface of the protective film 410b to the side surfaces of the protective films 410a and 410b, and extends to the surface of the sidewall 440. Specifically, between the adjacent light emitting elements 200, the wiring 208a is located below the cathode electrode 206 in the film thickness direction of the substrate 300. Furthermore, also in the present modification, the outer periphery of the upper surface of the cathode electrode 206 is exposed from the protective film 410a, and the exposed outer periphery is electrically connected to the wiring 208a.

Also in the present modification, as illustrated in FIG. 32, the wiring 208a is covered with the protective film 420. Also in the present modification, the protective film 412 formed of a low refractive index film is embedded between the adjacent light emitting elements 200. Furthermore, also in the present modification, the protective film 414 is provided so as to cover the upper surfaces of the protective films 412 and 420.

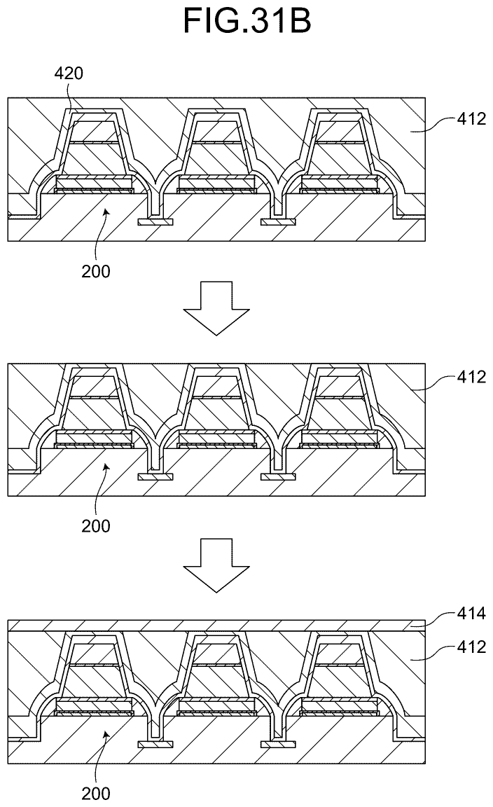

Next, a method of manufacturing the pixel 20 according to the second modification of the seventh embodiment of the present disclosure will be described with reference to FIGS. 33A and 33B. FIGS. 33A and 33B are explanatory diagrams for illustrating a method of manufacturing the pixel 20 according to the second modification of the present embodiment, and correspond to the cross-sectional view of FIG. 32.

First, as illustrated in the upper drawing of FIG. 33A, the anode electrode 202, the light emitting layer 204, the cathode electrode 206, and the protective film 410a are sequentially stacked on the substrate 300 to form the light emitting element 200. Furthermore, an insulating film 440a, which is to be a protective film 410b and the sidewall 440, is formed so as to cover the entire light emitting element 200. Next, a resist 450, being a patterned resist, is formed on the light emitting element 200.

Next, as illustrated in the second drawing from the top in FIG. 33A, the insulating film 440a is etched according to the pattern of the resist 450 so as to leave the protective film 410b on the protective film 410a. At this time, the protective film 410a is etched until the outer periphery of the upper surface of the cathode electrode 206 is exposed. Furthermore, at this time, the sidewall 440 is formed so as to fill the space between the light emitting elements 200 and cover the side surfaces of the anode electrode 202 and the light emitting layer 204.

Next, as illustrated in the third drawing from the top in FIG. 33A, the wiring 208a a is formed so as to cover the surface of the light emitting element 200 provided with the protective film 410b and the surface of the sidewall 440. At this time, the outer periphery of the upper surface of the cathode electrode 206 exposed from the protective film 410a is electrically connected to the wiring 208a.

Furthermore, as illustrated in the lower drawing of FIG. 33A, the protective film 420 is formed so as to cover the wiring 208a.

Next, as illustrated in the upper drawing of FIG. 33B, the protective film 412 is formed so as to fill the space between the light emitting elements 200. Subsequently, as illustrated in the middle drawing of FIG. 33B, the upper surface of the protective film 412 is planarized by a technique such as CMP. Furthermore, as illustrated in the lower drawing of FIG. 33B, the protective film 414 is further stacked on the protective film 412.

The manufacturing method described here is an example, and can be appropriately changed in the present modification.

### 10. Summary

As described above, according to each embodiment of the present disclosure, it is possible to improve the upward light extraction efficiency of the light emitting device 10.

Specifically, in each embodiment of the present disclosure, the trench 430 is provided in the protective film 410 on the light emitting element 200 so as to partition the adjacent light emitting elements 200, and the protective film 412 having the refractive index higher than the refractive index of the protective film 410 is embedded in the trench 430. With this configuration, in each embodiment of the present disclosure, by being bound by the protective film 410 and the protective film 412, the light beams from the light emitting layer 204 are reflected many times at the interface so as to be confined in the protective film 410 to interfere with each other. Accordingly, in each embodiment, the protective film 410 sandwiched between the trenches 430 functions like a waveguide, and can guide the light from the light emitting layer 204 upward while suppressing spreading of the light. As a result, in each embodiment, it is possible to improve the upward light extraction efficiency of the light emitting device 10.

Furthermore, the light emitting device 10 according to the embodiment of the present disclosure can be manufactured by using a method, a device, and conditions used for manufacturing a general semiconductor device. That is, the light emitting device 10 according to the present embodiment can be manufactured using an existing method for manufacturing a semiconductor device.

Examples of the above-described method include a physical vapor deposition (PVD) method, a chemical vapor deposition (CVD) method, and an atomic layer deposition (ALD) method. Examples of the PVD method include a vacuum vapor deposition method, an electron beam (EB) vapor deposition method, various sputtering methods (magnetron sputtering method, a Radio Frequency-Direct Current (RF-DC) coupled bias sputtering method, an electron cyclotron resonance (ECR) sputtering method, a facing target sputtering method, a radio frequency sputtering method, and the like), an ion plating method, a laser ablation method, a molecular beam epitaxy (MBE) method, a laser transfer method, and the like. Examples of the CVD method include a plasma CVD method, a thermal CVD method, a metal organic chemical CVD (MOCVD) method, and an optical CVD method. Furthermore, other methods include an electrolytic plating method, an electroless plating method, and a spin coating method; an immersion method; a casting method; micro-contact printing; a drop cast method; various printing methods such as a screen printing method, an inkjet printing method, an offset printing method, a gravure printing method, and a flexographic printing method; a stamping method; a spray method; and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendering coater method. Furthermore, examples of a patterning method of individual layers include: chemical etching such as shadow mask, laser transfer, and photolithography; and physical etching using ultraviolet rays, laser, and the like. In addition, examples of the planarization technique include a chemical mechanical polishing (CMP) method, a laser planarization method, and a reflow method.

### 11. Modification

### 11.1 First Modification

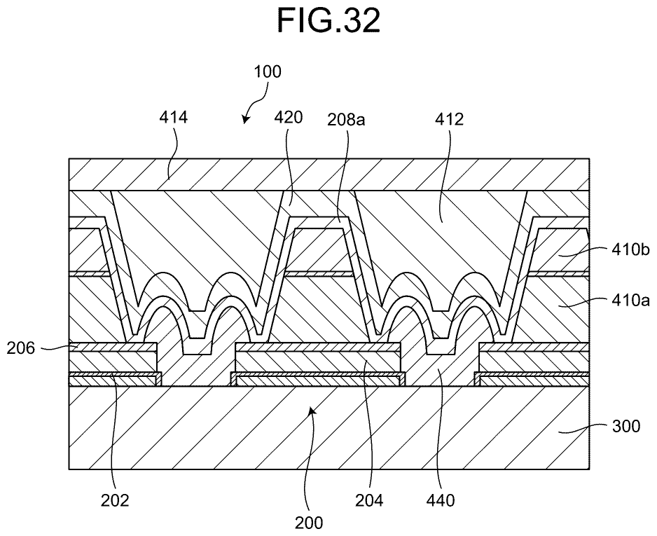

Next, with reference to FIGS. 34A to 34G, modifications of the embodiment of the present disclosure will be described as a modification of the relationship between a normal line LN passing through the center of the subpixel 100 (specifically, the center of the plurality of light emitting elements 200 included in one subpixel 100), a normal line LN′ passing through the center of the lens member (specifically, the on-chip lens 304), and a normal line LN″ passing through the center of a wavelength selector (specifically, the color filter 302). FIGS. 34A to 34G are conceptual diagrams for describing a relationship among a normal line LN passing through the center of a light emitting portion, a normal line LN′ passing through the center of the lens member, and a normal line LN″ passing through the center of the wavelength selector. Note that, in the following description, the center of the subpixel 100 is denoted as the center of the light emitting portion.

In the embodiment of the present disclosure, the size of the wavelength selector (for example, the color filter 302) may be appropriately varied according to the light emitted from the subpixel 100. Furthermore, in a case where a light absorption layer (black matrix layer) is provided between the subpixel 100 and a wavelength selector (for example, the color filter 302) of the adjacent subpixel 100, the size of the light absorption layer (black matrix layer) may be appropriately varied according to the light emitted from the subpixel 100. Furthermore, the size of the wavelength selector (for example, the color filter 302) may be appropriately varied according to a distance (offset amount) d₀ between the normal line passing through the center of the subpixel 100 and the normal line passing through the center of the color filter 302. The planar shape of the wavelength selector (for example, the color filter 302) may be the same as, similar to, or different from the planar shape of the lens member (for example, the on-chip lens 304).

For example, as illustrated in FIG. 34A, the normal line LN passing through the center of the light emitting portion, the normal line LN″ passing through the center of the wavelength selector, and the normal line LN′ passing through the center of the lens member may be aligned with each other. In other words, a distance (offset amount) D₀ between the normal line passing through the center of the light emitting portion and the normal line passing through the center of the lens member, as well as a distance (offset amount) d₀between the normal line passing through the center of the light emitting portion and the normal line passing through the center of the wavelength selector, can be equally set to 0 (zero).

Furthermore, for example, as illustrated in FIG. 34B, it is also allowable to set such that the normal line LN passing through the center of the light emitting portion and the normal line LN″ passing through the center of the wavelength selector are aligned with each other, but the normal line LN passing through the center of the light emitting portion and the normal LN″ passing through the center of the wavelength selector are not aligned with the normal line LN′ passing through the center of the lens member. In other words, D₀≠d₀=0 is allowable.

Furthermore, for example, as illustrated in FIG. 34C, it is also allowable to set such that the normal line LN passing through the center of the light emitting portion are not aligned with the normal line LN″ passing through the center of the wavelength selector and the normal line LN′ passing through the center of the lens member, and the normal line LN″ passing through the center of the wavelength selector are aligned with the normal line LN′ passing through the center of the lens member. In other words, D₀=d₀>0 is allowable.

Furthermore, for example, as illustrated in FIG. 34D, it is also allowable to use a mode in which the normal line LN passing through the center of the light emitting portion is not aligned with the normal line LN″ passing through the center of the wavelength selector, or the normal line LN′ passing through the center of the lens member, and the normal line LN′ passing through the center of the lens member is not aligned with the normal line LN passing through the center of the light emitting portion or the normal line LN″ passing through the center of the wavelength selector. Here, the center of the wavelength selector (indicated by a filled square in FIG. 34D) is preferably located on a straight line LL connecting the center of the light emitting portion and the center of the lens member (indicated by a filled circle in FIG. 34D). Specifically, when a distance from the center of the light emitting portion to the center of the wavelength selector in the thickness direction is LL₁, and a distance from the center of the wavelength selector to the center of the lens member in the thickness direction is LL₂, it is preferable that D₀>D₀>0 is satisfied, and it is preferable that D₀:D₀=LL₁: (LL₁+LL₂) is satisfied in consideration of manufacturing variations.

In addition, the stacking relationship between the wavelength distal end and the lens member may be interchanged. In such a case, for example, as illustrated in FIG. 34E, the normal line LN passing through the center of the light emitting portion, the normal line LN″ passing through the center of the wavelength selector, and the normal line LN′ passing through the center of the lens member may be aligned with each other. In other words, D₀=D₀=0 is allowable.

Furthermore, for example, as illustrated in FIG. 34F, it is allowable to set such that the normal line LN passing through the center of the light emitting portion are not aligned with the normal line LN″ passing through the center of the wavelength selector and the normal line LN′ passing through the center of the lens member, and the normal line LN″ passing through the center of the wavelength selector are aligned with the normal line LN′ passing through the center of the lens member. In other words, D₀=D₀>0 is allowable.

Furthermore, as illustrated in FIG. 34G being a conceptual diagram, it is also allowable to use a mode in which the normal line LN passing through the center of the light emitting portion is not aligned with the normal line LN″ passing through the center of the wavelength selector, or the normal line LN′ passing through the center of the lens member, and the normal line LN′ passing through the center of the lens member is not aligned with the normal line LN passing through the center of the light emitting portion or the normal line LN″ passing through the center of the wavelength selector. Here, the center of the wavelength selector is preferably located on a straight line LL connecting the center of the light emitting portion and the center of the lens member. Specifically, when a distance from the center of the light emitting portion to the center of the wavelength selector (indicated by a filled square in FIG. 34G) in the thickness direction is LL₁, and a distance from the center of the wavelength selector to the center of the lens member (indicated by a filled circle in FIG. 34G) in the thickness direction is LL₂, it is preferable that D₀>D₀>0 is satisfied, and it is preferable that D₀:D₀=LL₂: (LL₁+LL₂) is satisfied in consideration of manufacturing variations.

### 11.2 Second Modification

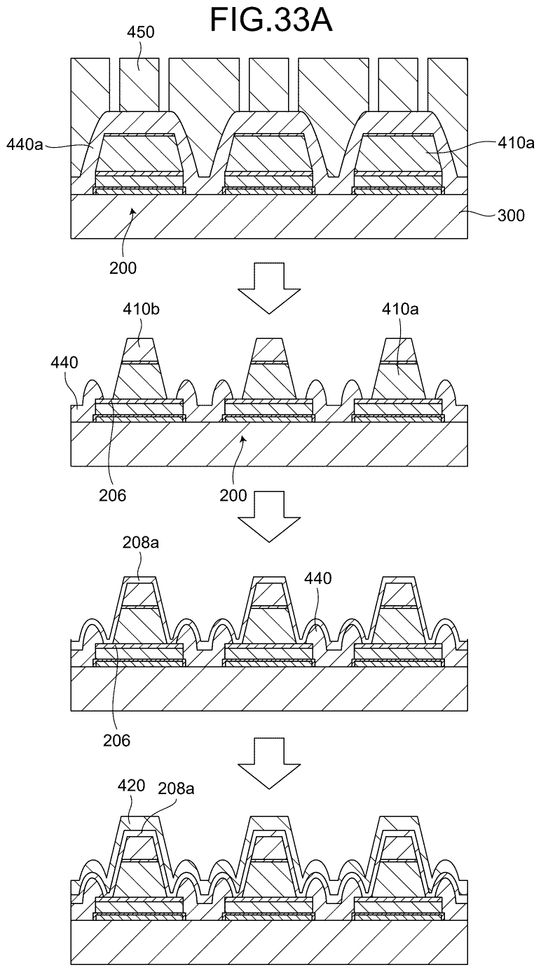

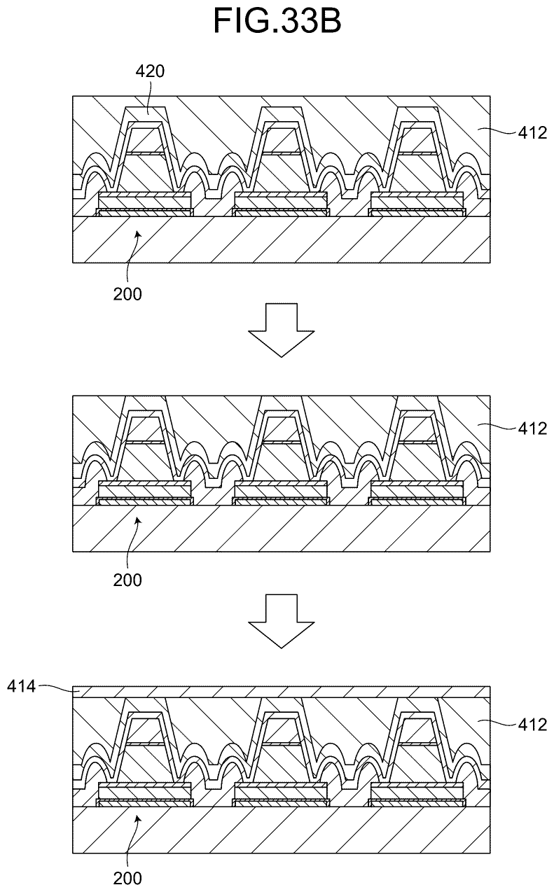

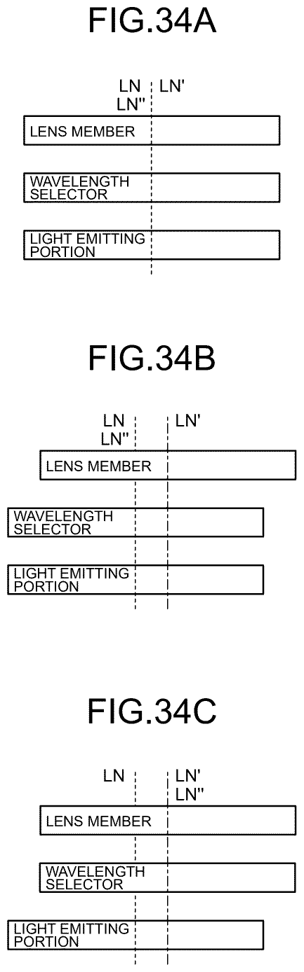

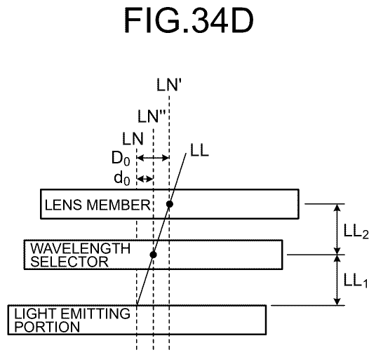

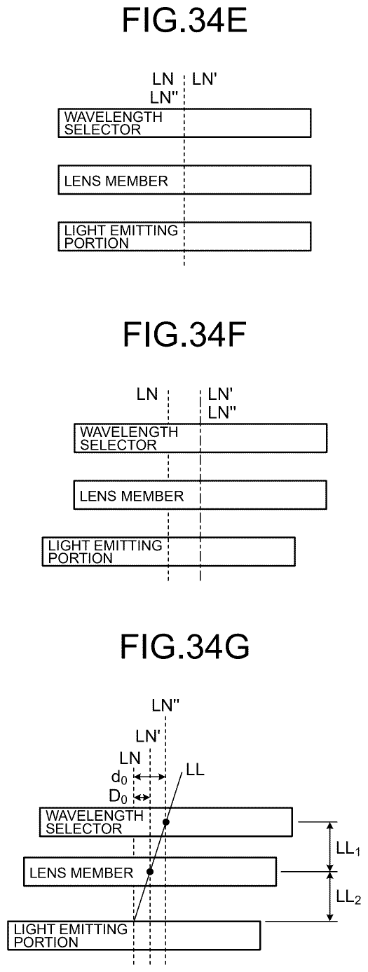

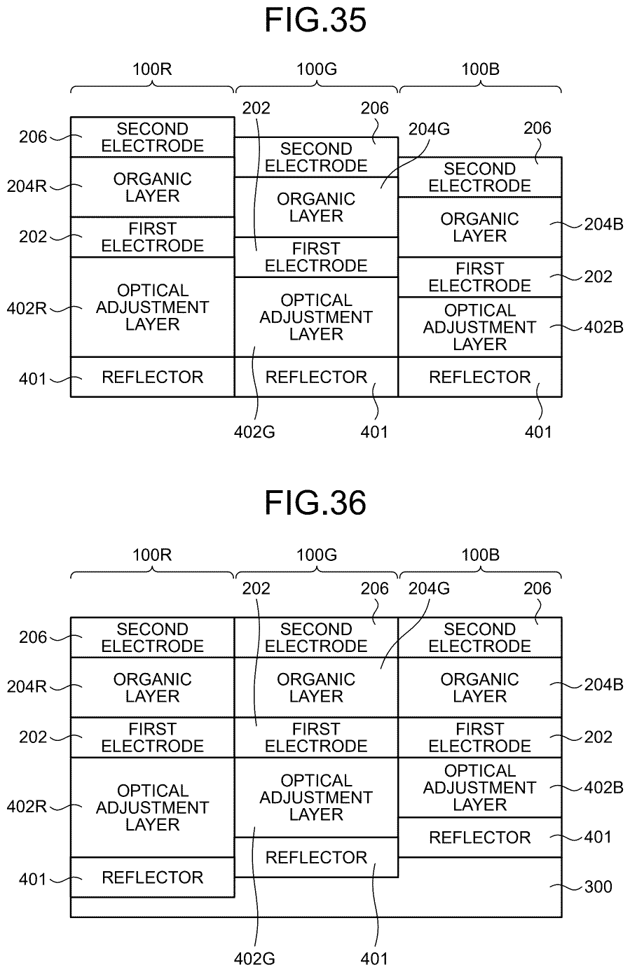

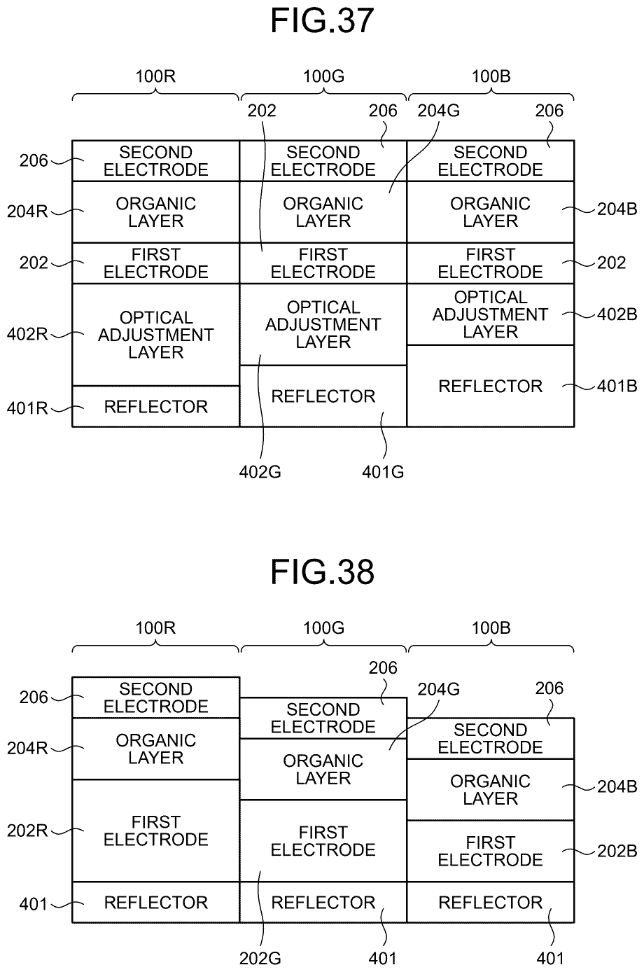

The subpixel 100 (specifically, the light emitting element 200) used in the light emitting device according to the embodiment of the present disclosure described above may include a resonator structure that allows light generated in the light emitting layer 204 to resonate. Hereinafter, the resonator structure will be described with reference to FIGS. 35 to 41. FIG. 35 is a schematic cross-sectional view for illustrating a first example of the resonator structure. FIG. 36 is a schematic cross-sectional view for illustrating a second example of the resonator structure. FIG. 37 is a schematic cross-sectional view for illustrating a third example of the resonator structure. FIG. 38 is a schematic cross-sectional view for illustrating a fourth example of the resonator structure. FIG. 39 is a schematic cross-sectional view for illustrating a fifth example of the resonator structure. Furthermore, FIG. 40 is a schematic cross-sectional view for illustrating a sixth example of the resonator structure. FIG. 41 is a schematic cross-sectional view for illustrating a seventh example of the resonator structure.

### Resonator Structure: First Example

FIG. 35 is a schematic cross-sectional view for illustrating the first example of the resonator structure. In the first example, a first electrode (for example, the anode electrode) 202 is formed with an identical film thickness in each subpixel 100. The similar applies to a second electrode (for example, the cathode electrode) 206.

As illustrated in FIG. 35, under the first electrode 202 of the subpixel 100, there is provided a reflector 401 with an optical adjustment layer 402 interposed between the first electrode 202 and the reflector 401. A resonator structure that resonates light generated by the organic layer (specifically, the light emitting layer) 204 is formed between the reflector 401 and the second electrode 206.

The reflector 401 is formed with an identical film thickness in each subpixel 100. The film thickness of the optical adjustment layer 402 varies depending on the color to be displayed by the subpixel 100. Since the optical adjustment layers 402R, 402G, and 402B have various film thicknesses, it is possible to set an optical distance capable of producing optimum resonance for a wavelength of light corresponding to a color to be displayed.

In the example illustrated in FIG. 35, the upper surfaces of the reflectors 401 in the subpixels 100R, 100G, and 100B are arranged so as to be aligned. As described above, since the film thickness of the optical adjustment layer 402 varies depending on the color to be displayed by the subpixel 100, the position of the upper surface of the second electrode 206 varies depending on the types of the Subpixels 100R, 100G, and 100B.

The reflector 401 can be formed using, for example, a metal such as aluminum (Al), silver (Ag), or copper (Cu), or an alloy containing these as a main component.

The optical adjustment layer 402 can be formed of an inorganic insulating material such as silicon nitride (SiNx), silicon oxide (SiOx), or silicon oxynitride (SiOxNy), or an organic resin material such as an acrylic resin or a polyimide resin. The optical adjustment layer 402 may be a single layer or a stacked film of a plurality of materials. Furthermore, the number of stacked layers may be varied according to the type of the subpixel 100.

The first electrode 202 can be formed using, for example, a transparent conductive material such as indium tin oxide (ITO), indium zinc oxide (IZO), or zinc oxide (ZnO).

The second electrode 206 preferably functions as a semi-transparent reflective film. The second electrode 206 can be formed using materials such as magnesium (Mg), silver (Ag), a magnesium-silver alloy (MgAg) containing these as a main component, or an alloy containing an alkali metal or an alkaline earth metal.

### Resonator Structure: Second Example

FIG. 36 is a schematic cross-sectional view for illustrating a second example of the resonator structure. Also in the second example, the first electrode 202 and the second electrode 206 are formed with an identical film thickness in each subpixel 100.

Also in the second example, under the first electrode 202 of the subpixel 100, there is provided a reflector 401 with an optical adjustment layer 402 interposed between the first electrode 202 and the reflector 401. A resonator structure that resonates light generated by the organic layer 204 is formed between the reflector 401 and the second electrode 206. Similarly to the first example, the reflector 401 is formed with an identical film thickness in each subpixel 100, and the film thickness of the optical adjustment layer 402 varies depending on the color to be displayed by the subpixel 100.

In the first example illustrated in FIG. 35, the upper surfaces of the reflectors 401 in the subpixels 100R, 100G, and 100B are arranged to be aligned, while the positions of the upper surfaces of the second electrodes 206 are varied depending on the types of the subpixels 100R, 100G, and 100B.

In contrast, in the second example illustrated in FIG. 36, the upper surfaces of the second electrodes 206 are arranged to be aligned in the subpixels 100R, 100G, and 100B. In order to align the upper surfaces of the second electrodes 206, the upper surfaces of the reflectors 401 in the subpixels 100R, 100G, and 100B are varied according to the types of the subpixels 100R, 100G, and 100B. Accordingly, the lower surface of the reflector 401 has a stepped shape according to the types of the subpixels 100R, 100G, and 100B.

Conditions such as materials constituting the reflector 401, the optical adjustment layer 402, the first electrode 202, and the second electrode 206 are similar to the description in the first example, and thus the description thereof is omitted.

### Resonator Structure: Third Example

FIG. 37 is a schematic cross-sectional view for illustrating a third example of the resonator structure. Also in the third example, the first electrode 202 and the second electrode 206 are formed with an identical film thickness in each subpixel 100.

Also in the third example, under the first electrode 202 of the subpixel 100, there is provided a reflector 401 with an optical adjustment layer 402 interposed between the first electrode 202 and the reflector 401. A resonator structure that resonates light generated by the organic layer 204 is formed between the reflector 401 and the second electrode 206. Similarly to the first example and the second example, the film thickness of the optical adjustment layer 402 varies depending on the color to be displayed by the subpixel 100. In addition, similarly to the second example, the positions of the upper surfaces of the second electrodes 206 are arranged to be aligned in the subpixels 100R, 100G, and 100B.

In the second example illustrated in FIG. 36, in order to align the upper surfaces of the second electrodes 206, the lower surface of the reflector 401 has a stepped shape according to the types of the subpixels 100R, 100G, and 100B.

In contrast, in the third example illustrated in FIG. 37, the film thickness of the reflector 401 is set to vary according to the types of the subpixels 100R, 100G, and 100B. More specifically, the film thickness is set to align the lower surfaces of the reflectors 401R, 401G, and 401B.

Conditions such as materials constituting the reflector 401, the optical adjustment layer 402, the first electrode 202, and the second electrode 206 are similar to the description in the first example, and thus the description thereof is omitted.

### Resonator Structure: Fourth Example

FIG. 38 is a schematic cross-sectional view for illustrating a fourth example of the resonator structure.

In the first example illustrated in FIG. 35, the first electrode 202 and the second electrode 206 of the subpixel 100 are formed with an identical film thickness. In addition, under the first electrode 202 of the subpixel 100, there is provided a reflector 401 with an optical adjustment layer 402 interposed between the first electrode 202 and the reflector 401.

In contrast, the fourth example illustrated in FIG. 38 omits the optical adjustment layer 402, and sets the film thickness of the first electrode 202 to vary according to the types of the subpixels 100R, 100G, and 100B.

The reflector 401 is formed with an identical film thickness in each subpixel 100. The film thickness of the first electrode 202 varies depending on the color to be displayed by the subpixel 100. Since the first electrodes 202R, 202G, and 202B have various film thicknesses, it is possible to set an optical distance capable of producing optimum resonance for a wavelength of light corresponding to a color to be displayed.

Conditions such as materials constituting the reflector 401, the first electrode 202, and the second electrode 206 are similar to the description in the first example, and thus the description thereof is omitted.

### Resonator Structure: Fifth Example

FIG. 39 is a schematic cross-sectional view for illustrating a fifth example of the resonator structure.

In the first example illustrated in FIG. 35, the first electrode 202 and the second electrode 206 are formed with an identical film thickness in each subpixel 100. In addition, under the first electrode 202 of the subpixel 100, there is provided a reflector 401 with an optical adjustment layer 402 interposed between the first electrode 202 and the reflector 401.

In contrast, the fifth example illustrated in FIG. 39, omits the optical adjustment layer 402, and instead, has an oxide film 404 formed on the surface of the reflector 401. The film thickness of the oxide film 404 is set to vary according to the types of the subpixels 100R, 100G, and 100B.

The film thickness of the oxide film 404 varies depending on the color to be displayed by the subpixel 100. Since the oxide films 404R, 404G, and 404B have various film thicknesses, it is possible to set an optical distance capable of producing optimum resonance for a wavelength of light corresponding to a color to be displayed.

The oxide film 404 is a film obtained by oxidizing the surface of the reflector 401, and is formed of a material such as aluminum oxide, tantalum oxide, titanium oxide, magnesium oxide, or zirconium oxide. The oxide film 404 functions as an insulating film for adjusting an optical path length (optical distance) between the reflector 401 and the second electrode 206.

The oxide film 404 having various film thicknesses depending on the types of the subpixels 100R, 100G, and 100B can be formed as follows, for example.

First, an electrolytic solution is filled in a container, and then, a substrate on which the reflector 401 is formed is immersed in the electrolytic solution. Furthermore, an electrode is disposed so as to face the reflector 401.

Subsequently, a positive voltage is applied to the reflector 401 with reference to the electrode so as to anodize the reflector 401. The film thickness of the oxide film due to the anodization is proportional to the voltage value with respect to the electrode. Accordingly, anodization is performed in a state where voltages corresponding to the types of the subpixels 100R, 100G, and 100B are applied to the reflectors 401R, 401G, and 401B, respectively. This can collectively form the oxide films 404 having various film thicknesses.

Conditions such as materials constituting the reflector 401, the first electrode 202, and the second electrode 206 are similar to the description in the first example, and thus the description thereof is omitted.

### Resonator Structure: Sixth Example

FIG. 40 is a schematic cross-sectional view for illustrating a sixth example of the resonator structure. In the sixth example, the subpixel 100 is constituted with a stack of the first electrode 202, the organic layer 204, and the second electrode 206. However, in the sixth example, the first electrode 202 is formed to function as an electrode and a reflector. The first electrode (also reflector) 202 is formed of a material having an optical constant selected according to the type of the subpixels 100R, 100G, and 100B. Due to the difference in the phase shift by the first electrode (also serving as the reflector) 202, it is possible to set an optical distance that generates optimum resonance for the wavelength of light according to the color to be displayed.

The first electrode (also serving as the reflector) 202 can be formed of a single metal such as aluminum (Al), silver (Ag), gold (Au), or copper (Cu), or an alloy containing these as a main component. For example, the first electrode (also serving as the reflector) 202R of the subpixel 100R may be formed of copper (Cu), while the first electrode (also serving as the reflector) 100G of the subpixel 202G and the first electrode (also serving as the reflector) 100B of the subpixel 202B may be formed of aluminum.

Conditions such as materials constituting the second electrode 206 are similar to the description in the first example, and thus the description thereof is omitted.

### Resonator Structure: Seventh Example

FIG. 41 is a schematic cross-sectional view for illustrating a seventh example of the resonator structure. In the seventh example, basically, the sixth example is applied to the subpixels 100R and 100G, and the first example is applied to the subpixel 100B. Also in this configuration, it is possible to set an optical distance capable of producing optimum resonance for the wavelength of light according to the color to be displayed.

The first electrode (also serving as the reflector) 202R and 202G, respectively used for the subpixel 100R and 100G, can be formed of a single metal such as aluminum (Al), silver (Ag), gold (Au), or copper (Cu), or an alloy containing these as a main component.

Conditions such as materials constituting the reflector 401B, the optical adjustment layer 402B, and the first electrode 202B, which are used for the subpixel 100B, are similar to the description in the first example, and thus the description thereof is omitted.

### 12. Application Example

For example, the technology according to the present disclosure may be applied to a display section or the like of various electronic devices. Accordingly, examples of electronic devices to which the present technology is applicable will be described below.

### Specific Example 1

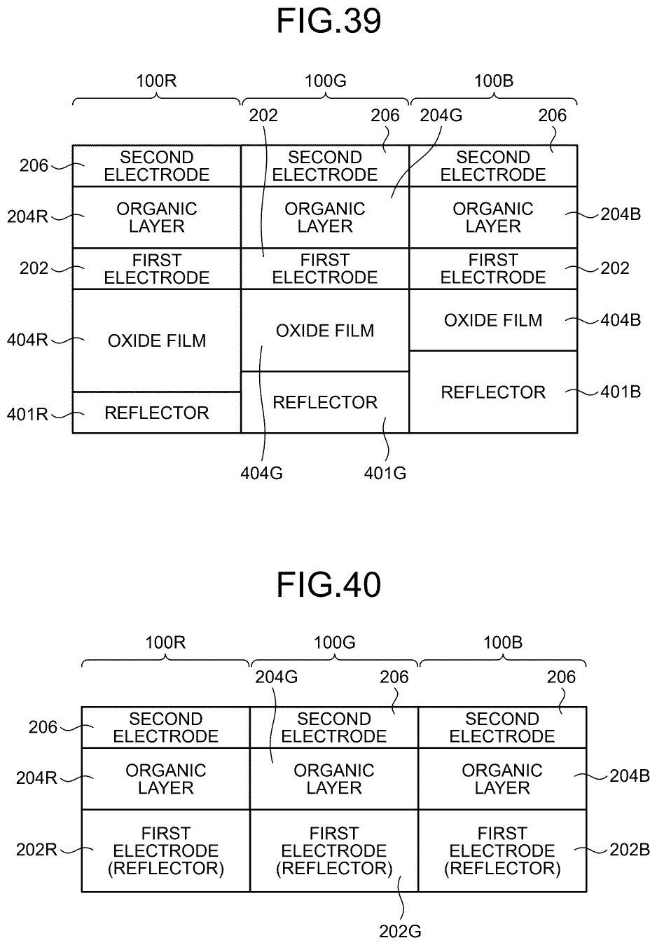

FIG. 42A is a front view illustrating an example of an external appearance of a digital still camera 500. FIG. 42B is a rear view illustrating an example of an external appearance of the digital still camera 500. The digital still camera 500, being a lens interchangeable single lens reflex type camera, includes: an imaging lens unit (interchangeable lens) 512 being an interchangeable lens unit on substantially center of the front surface of a camera main body (camera body) 511; and a grip 513 to be held by a photographer on the left side on the front surface, for example.

There is provided a monitor 514 on the back surface of the camera main body 511 at a position shifted to the left from the center of the surface. There is provided an electronic view finder (eyepiece window) 515 above the monitor 514. Through the electronic view finder 515, the photographer can visually recognize an optical image of a subject guided by the imaging lens unit 512 and determine the composition. The light emitting device 10 according to the embodiment of the present disclosure can be used as the monitor 514 and the electronic view finder 515.

### Specific Example 2

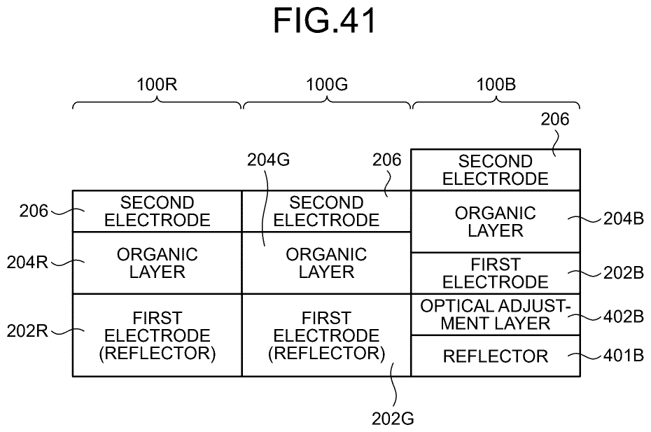

FIG. 43 is an external view of a head-mounted display 600. The head-mounted display 600 includes an earpiece 612 on each side of a display section 611 having an eyeglass shape, for example, used to fit the head-mounted display 600 on the head of the user. In the head-mounted display 600, the light emitting device 10 according to the embodiment of the present disclosure can be used as the display section 611.

### Specific Example 3

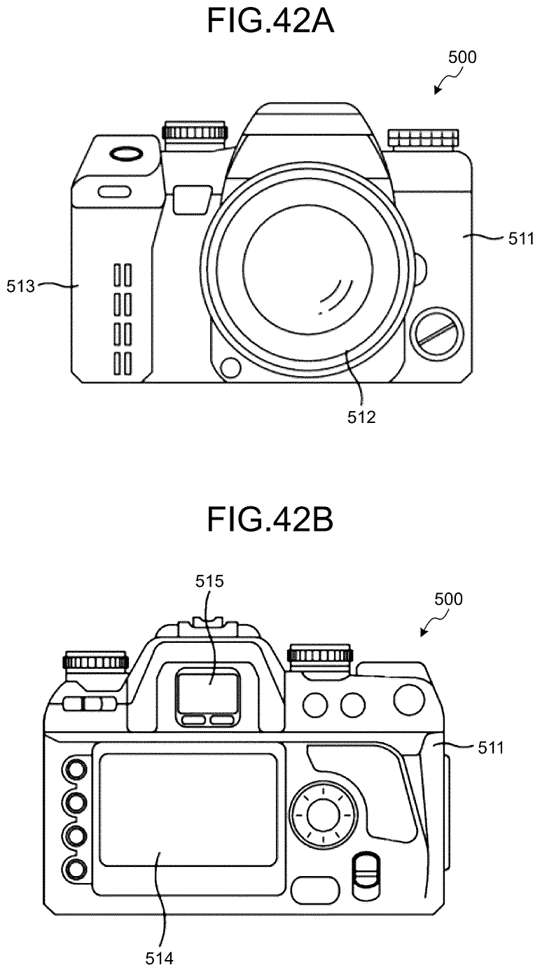

FIG. 44 is an external view of a see-through head-mounted display 634. The see-through head-mounted display 634 includes a main body 632, an arm 633, and a lens barrel 631.

The main body 632 is connected to the arm 633 and eye-glasses 630. Specifically, an end of the main body 632 in the long side direction is coupled to the arm 633, while one side of a side surface of the main body 632 is coupled to the eye-glasses 630 via a connecting member. Alternatively, that the main body 632 may be directly mounted on the head of a person.

The main body 632 incorporates a control substrate and a display section for controlling the operation of the see-through head-mounted display 634. The arm 633 connects the main body 632 and the lens barrel 631 to each other and supports the lens barrel 631. Specifically, the arm 633 is coupled to the end of the main body 632 and the end of the lens barrel 631, and fixes the lens barrel 631. Furthermore, the arm 633 incorporates a signal line for communicating data related to an image supplied from the main body 632 to the lens barrel 631.

The lens barrel 631 projects image light supplied from the main body 632 via the arm 633 toward the eyes of the user wearing the see-through head-mounted display 634 through an eyepiece. In the see-through head-mounted display 634, the light emitting device 10 according to the embodiment of the present disclosure can be used for the display section of the main body 632.

### Specific Example 4

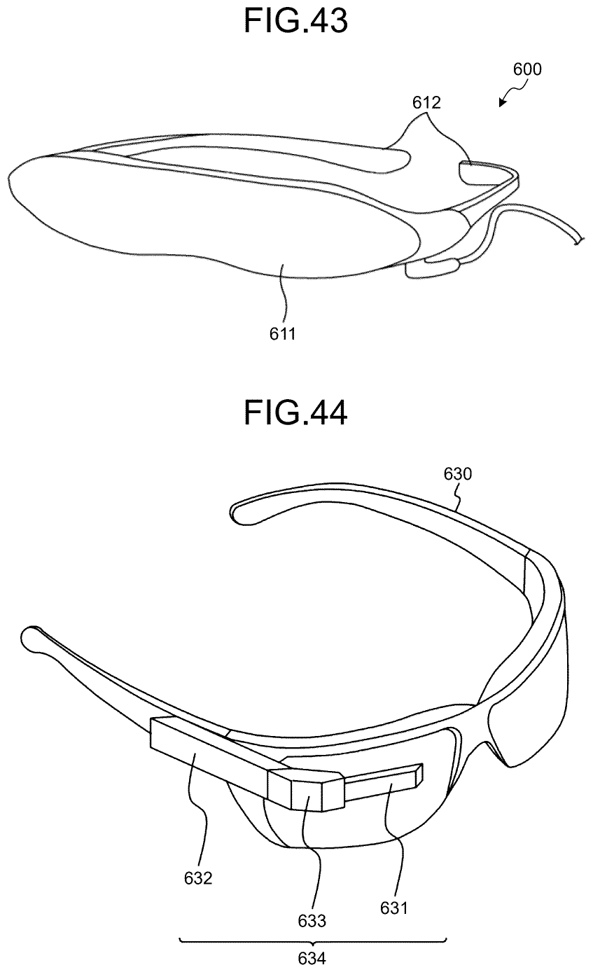

FIG. 45 illustrates an example of an external appearance of a television device 710. The television device 710 includes, for example, a video display screen 711 including a front panel 712 and glass filter 713. The video display screen 711 is constituted with the light emitting device 10 according to the embodiment of the present disclosure.

### Specific Example 5

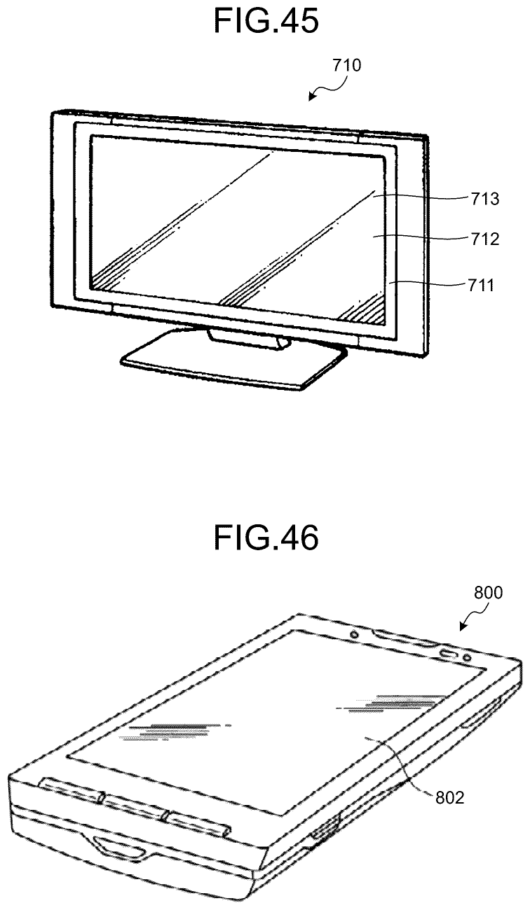

FIG. 46 illustrates an example of an external appearance of a smartphone 800. The smartphone 800 includes a display section 802 that displays various types of information, an operation portion including a button that receives an operation input by the user, and the like. The display section 802 can be implemented by the light emitting device 10 according to the present embodiment.

### Specific Example 6

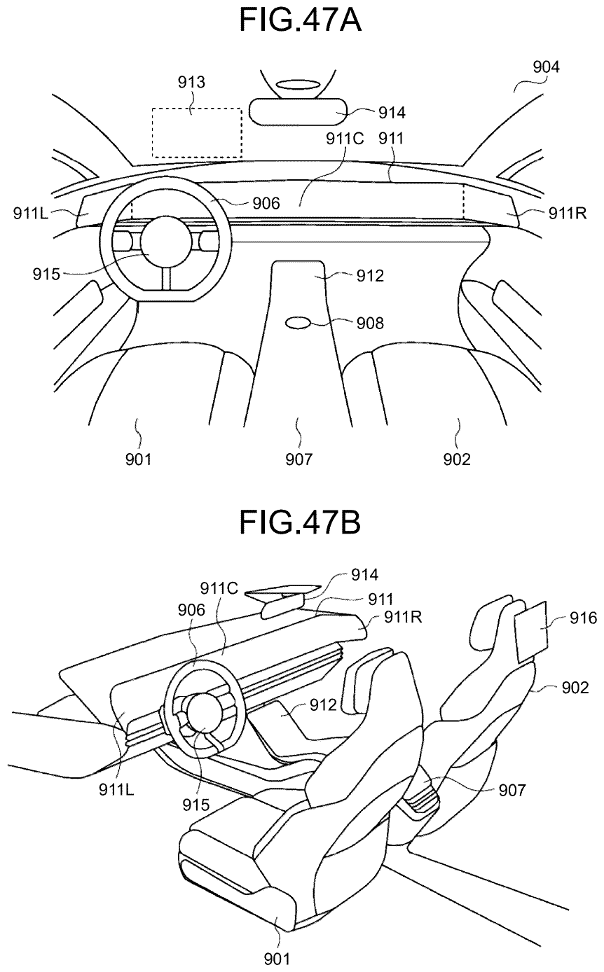

FIGS. 47A and 47B are views illustrating an internal configuration of an automobile having the light emitting device 10 according to the embodiment of the present disclosure as a display device. Specifically, FIG. 47A is a view illustrating an internal state of the automobile from the rear toward the front of the automobile, and FIG. 47B is a view illustrating an internal state of the automobile from the oblique rear toward the oblique front of the automobile.

The automobile illustrated in FIGS. 47A and 47B has a center display 911, a console display 912, a head-up display 913, a digital rear mirror 914, a steering wheel display 915, and a rear seat entertainment display 916. The light emitting device 10 according to the embodiment of the present disclosure is applicable to some or all of these displays.

The center display 911 is disposed on a center console 907 at a position facing a driver's seat 901 and a passenger seat 902. FIGS. 47A and 47B illustrate an example of the center display 911 having a horizontally long shape extending from the driver's seat 901 side to the passenger seat 902 side, but the screen size and the layout of the center display 911 can be optionally determined. The center display 911 can display information detected by various sensors (not illustrated). As a specific example, the center display 911 can display information such as: a captured image captured by an image sensor; a distance image to an obstacle in front of or on a side of the vehicle measured by a time of flight (ToF) sensor; and a passenger's body temperature detected by an infrared sensor. The center display 911 can be used to display, for example, at least one of safety information, operational information, a lifelog, health information, authentication/identification information, and entertainment information.

The safety information includes information such as drowsiness detection, distracted driving detection, on-board child mischief detection, seat belt wearing check, and left-behind occupant presence detection, being information detected by a sensor (not illustrated) superimposed on the back side of the center display 1911, for example. The operational information detects a gesture related to the operation of the occupant using the sensor. The gesture to be detected may include operation of various equipment in the automobile. For example, the sensor detects an operation of air conditioning equipment, a navigation device, an audio/visual (AV) device, a lighting device, or the like. The lifelog includes a lifelog of all the occupants. For example, the lifelog includes an action record of each occupant in the vehicle. By acquiring and storing the lifelog, it is possible to confirm the state of the occupant at the time of an accident. The health information detects the body temperature of the occupant using a temperature sensor, and estimates the health state of the occupant based on the detected body temperature. Alternatively, the face of the occupant may be imaged using an image sensor to estimate the health state of the occupant from the imaged facial expression. Furthermore, automated voice may be used to make a conversation with the occupant so as to estimate health conditions of the occupant based on the replies from the occupant. The authentication/identification information includes a keyless entry function based on face authentication using a sensor, and a sheet height position automatic adjustment function based on face identification. The entertainment information includes a function of using a sensor to detect operation information regarding AV devices by the occupant, and a function of using a sensor to recognize the face of the occupant and provide content suitable for the occupant via the AV device.

The console display 912 can be used to display lifelog information, for example. The console display 912 is disposed near a gear lever 908 of the center console 907 between the driver's seat 901 and the passenger seat 902. The console display 912 can also display information detected by various sensors (not illustrated). In addition, the console display 912 may display surrounding images of the vehicle captured by the image sensor, or may display a distance image to an obstacle in the surroundings of the vehicle.

The head-up display 913 is virtually displayed at a deeper position of a windshield 904 in front of the driver's seat 901. The head-up display 913 can be used to display, for example, at least one of safety information, operation information, a lifelog, health information, authentication/identification information, and entertainment information. The head-up display 913 is virtually disposed in front of the driver's seat 901 in many cases, and thus is suitable for displaying information directly related to the operation of the automobile, such as the speed of the automobile and the fuel (battery) level.

The digital rear mirror 914 can display not only the rear view of the vehicle but also the state of the occupant in the back seat, and thus can be used to display lifelog information, for example, by disposing a sensor (not illustrated) to overlap the back surface side of the digital rear mirror 914.

The steering wheel display 915 is disposed near the center of a steering wheel 906 of the automobile. The steering wheel display 915 can be used to display, for example, at least one of safety information, operation information, a lifelog, health information, authentication/identification information, and entertainment information. In particular, the steering wheel display 915 is located close to the driver's hand, and thus is suitable for displaying lifelog information such as the body temperature of the driver, or for displaying information related to the operation of devices such as AV devices and the air conditioning equipment.

The rear seat entertainment display 916 is mounted on the back side of the driver's seat 901 and/or the passenger seat 902 so as to allow viewing by an occupant in the rear seat. The rear seat entertainment display 916 can be used to display, for example, at least one of safety information, operational information, a lifelog, health information, authentication/identification information, and entertainment information. In particular, the rear seat entertainment display 916 is in front of the occupant in the back seat, and thus can display information related to the occupant in the back seat. For example, the display may display information regarding the operation of the AV device or the air conditioning equipment, or a result of measuring the body temperature or the like of the occupant in the back seat by a temperature sensor (not illustrated).

### 13. Supplement

The preferred embodiments of the present disclosure have been described in detail above with reference to the accompanying drawings. However, the technical scope of the present disclosure is not limited to such examples. It will be apparent to those skilled in the art of the present disclosure that combinations of various embodiments, various modifications and alterations can be conceived within the scope of the technical idea described in the claims and naturally fall within the technical scope of the present disclosure.

Furthermore, the effects described in the present specification are merely illustrative or exemplary and are not limited. That is, the technology according to the present disclosure can exhibit other effects that are apparent to those skilled in the art from the description of the present specification in addition to or instead of the above effects.

Note that the present technology can also have the following compositions.

(1) A light emitting device comprising a plurality of light emitting elements arrayed on a substrate, wherein
each of the light emitting elements includes:
a first electrode provided on the substrate;
a light emitting layer stacked on the first electrode to emit light;
a second electrode stacked on the light emitting layer to transmit the light from the light emitting layer; and
a first protective film stacked on the second electrode to transmit the light from the light emitting layer,
the first protective films of the adjacent light emitting elements are provided to be continuous with each other,
the first protective film has a first trench that partitions the adjacent light emitting elements, and
a low refractive index film having a refractive index lower than a refractive index of the first protective film is embedded in the first trench.
   (2) The light emitting device according to (1), wherein a difference in refractive index between the low refractive index film and the first protective film is 0.2 or less.
   (3) The light emitting device according to (1) or (2), wherein the low refractive index film is provided so as to cover an upper surface of the first protective film.
   (4) The light emitting device according to (1) or (2), further comprising
a second protective film stacked on the first protective film, wherein
the second protective film has a refractive index higher than the refractive index of the low refractive index film.
   (5) The light emitting device according to (4), wherein
the second protective film has a refractive index equivalent to or lower than the refractive index of the first protective film.
   (6) The light emitting device according to (4) or (5), wherein the second protective film covers the low refractive index film.
   (7) The light emitting device according to (6), wherein a part of the low refractive index film protruding from the first trench has a lens shape.
   (8) The light emitting device according to (4) or (5), wherein the second protective film is divided by a part of the low refractive index film protruding from the first trench.
   (9) The light emitting device according to (8), further comprising a color filter stacked on the second protective film.
   (10) The light emitting device according to (9), wherein the part of the low refractive index film protruding from the first trench is in contact with the color filter.
   (11) The light emitting device according to (9), wherein the part of the low refractive index film protruding from the first trench divides the color filter.
   (12) The light emitting device according to any one of (9) to (11), wherein
the second protective film has a refractive index between the refractive index of the first protective film and a refractive index of the color filter.
   (13) The light emitting device according to any one of (4) to (6), wherein the second protective film is embedded in a part of the first trench.
   (14) The light emitting device according to any one of (1) to (13), wherein the first trench has a tapered shape expanding upward.
   (15) The light emitting device according to any one of (1) to (14), wherein parts of the second electrodes of the adjacent light emitting elements are electrically connected to each other.
   (16) The light emitting device according to any one of (4) to (13), wherein
each of the light emitting elements includes:
a contact hole provided in the first protective film to expose a part of an upper surface of the second electrode; and
first wiring to cover at least a part of a side surface of the contact hole, and
the first wiring is covered with the first protective film.
   (17) The light emitting device according to (16), wherein the low refractive index film is embedded in the contact hole.
   (18) The light emitting device according to (16), wherein the second protective film is embedded in the contact hole.
   (19) The light emitting device according to (1) or (2), wherein
each of the light emitting elements includes:
a contact hole provided in the first protective film to expose a part of an upper surface of the second electrode; and
second wiring covering at least a part of a side surface of the contact hole,
the second wiring is covered with the first protective film, and
a first color conversion film is embedded in at least a part of the contact hole in at least a part of the plurality of light emitting elements.
   (20) The light emitting device according to (19), wherein the light emitting element having the contact hole in which the first color conversion film is embedded and the light emitting element having the contact hole in which the first color conversion film is not embedded emit light of different colors.
   (21) The light emitting device according to (19), wherein the first color conversion film is at least embedded in at least a part of the contact holes of all the light emitting elements among the plurality of light emitting elements.
   (22) The light emitting device according to any one of (19) to (21), wherein
the first color conversion film has a higher refractive index than the refractive index of the low refractive index film.
   (23) The light emitting device according to any one of (19) to (22), wherein the first color conversion film is provided so as to fill the entire contact hole.
   (24) The light emitting device according to (23), wherein each of the light emitting elements further includes a second color conversion film stacked on the first color conversion film.
   (25) The light emitting device according to (24), wherein the second color conversion film is in contact with the low refractive index film embedded in the first trench.
   (26) The light emitting device according to (23), wherein
each of the light emitting elements further includes a third protective film stacked on the first color conversion film, and
the third protective film has a higher refractive index than the refractive index of the low refractive index film.
   (27) The light emitting device according to (26), wherein each of the light emitting elements further includes a third color conversion film stacked on the third protective film.
   (28) The light emitting device according to any one of (19) to (22), wherein
a fourth protective film is embedded in a bottom portion of the contact hole, and
the first color conversion film is stacked on the fourth protective film.
   (29) The light emitting device according to (28), wherein the fourth protective film has a higher refractive index than the refractive index of the low refractive index film.
   (30) The light emitting device according to any one of (19) to (29), wherein the first color conversion film is a color filter having a color of red, blue, or green.
   (31) The light emitting device according to any one of (1) to (14), wherein
each of the light emitting elements further includes third wiring electrically connected to at least a part of an outer periphery of an upper surface of the second electrode, and
the second electrode is electrically connected to the second electrode of the adjacent light emitting element via the third wiring.
   (32) The light emitting device according to (31), wherein each of the light emitting elements further includes a sidewall portion covering a side surface of the first electrode and a side surface of the light emitting layer, and the third wiring extends onto the sidewall portion.
   (33) The light emitting device according to (32), wherein
the first protective film includes:
a fifth protective film stacked on the second electrode; and
a sixth protective film covering the fifth protective film and the sidewall portion,
the sixth protective films of the adjacent light emitting elements are provided so as to be continuous with each other, and
the third wiring extends onto an upper surface and a side surface of the fifth protective film.
   (34) The light emitting device according to any one of (31) to (33), wherein the third wiring is electrically connected to a contact provided between the adjacent light emitting elements.
   (35) The light emitting device according to (34), further comprising
a second trench provided between the adjacent light emitting elements on the substrate, the second trench exposing an upper surface of the contact, wherein
the third wiring extends to at least a part of a side surface of the second trench.
   (36) The light emitting device according to (32) or (33), wherein
the sidewall portion is provided so as to be embedded between the adjacent light emitting elements.
   (37) The light emitting device according to any one of (1) to (36), wherein the light emitting element has a polygonal shape, a circular shape, or an elliptical shape.
   (38) The light emitting device according to any one of (1) to (32), wherein
the light emitting layer emits at least one of white light, red light, green light, or blue light.
   (39) An electronic device equipped with a light emitting device, the light emitting device including a plurality of light emitting elements arrayed on a substrate, wherein
each of the light emitting elements includes:
a first electrode provided on the substrate;
a light emitting layer stacked on the first electrode to emit light;
a second electrode stacked on the light emitting layer to transmit the light from the light emitting layer; and
a first protective film stacked on the second electrode to transmit the light from the light emitting layer,
the first protective films of the adjacent light emitting elements are provided to be continuous with each other,
the first protective film has a first trench that partitions the adjacent light emitting elements, and
a low refractive index film having a refractive index lower than a refractive index of the first protective film is embedded in the first trench.

### REFERENCE SIGNS LIST

10, 10a LIGHT EMITTING DEVICE
11 HORIZONTAL DRIVE CIRCUIT
12 VERTICAL DRIVE CIRCUIT
20, 20a PIXEL
100, 100B, 100G, 100N, 100R, SUBPIXEL
200, 200a LIGHT EMITTING ELEMENT
202, 202B, 202G, 202R ANODE ELECTRODE
204, 204a LIGHT EMITTING LAYER
206 CATHODE ELECTRODE
208, 208a WIRING
210, 410, 410a, 410b, 412, 414, 416, 418, 420 PROTECTIVE FILM
212 CONTACT
300 SUBSTRATE
302, 302a, 302b, 302c COLOR FILTER
304 ON-CHIP LENS
401, 401B, 401G, 401R REFLECTOR
402, 402B, 402G, 402R OPTICAL ADJUSTMENT LAYER
404, 404B, 404G, 404R OXIDE FILM
430, 434 TRENCH
432 CONTACT HOLE
440 SIDEWALL
440a INSULATING FILM
450 RESIST
500 DIGITAL STILL CAMERA
511 CAMERA MAIN BODY
512 IMAGING LENS UNIT
513 GRIP
514 MONITOR
515 ELECTRONIC VIEW FINDER
600 HEAD-MOUNTED DISPLAY
611, 802 DISPLAY SECTION
612 EARPIECE
630 EYE-GLASSES
631 LENS BARREL
632 MAIN BODY
633 ARM
634 SEE-THROUGH HEAD-MOUNTED DISPLAY
710 TELEVISION DEVICE
711 VIDEO DISPLAY SCREEN
712 FRONT PANEL
713 GLASS FILTER
800 SMARTPHONE
901 DRIVER'S SEAT
902 PASSENGER SEAT
904 WINDSHIELD
906 STEERING WHEEL
907 CENTER CONSOLE
908 GEAR LEVER
911 CENTER DISPLAY
912 CONSOLE DISPLAY
913 HEAD-UP DISPLAY
914 DIGITAL REAR MIRROR
915 STEERING WHEEL DISPLAY
916 REAR SEAT ENTERTAINMENT DISPLAY
C₁ CAPACITOR
C_{EL} CAPACITANCE
DTLₙ SIGNAL LINE
ELP LIGHT EMITTING ELEMENT
PS1m POWER FEED LINE
PS2 COMMON POWER FEED LINE
SCLₘ SCANNING LINE
TR_{w} WRITE TRANSISTOR
TR_{D} DRIVE TRANSISTOR

1. A light emitting device comprising a plurality of light emitting elements arrayed on a substrate, wherein
each of the light emitting elements includes:
a first electrode provided on the substrate;
a light emitting layer stacked on the first electrode to emit light;
a second electrode stacked on the light emitting layer to transmit the light from the light emitting layer; and
a first protective film stacked on the second electrode to transmit the light from the light emitting layer,
the first protective films of the adjacent light emitting elements are provided to be continuous with each other,
the first protective film has a first trench that partitions the adjacent light emitting elements, and
a low refractive index film having a refractive index lower than a refractive index of the first protective film is embedded in the first trench.

2. The light emitting device according to claim 1, wherein a difference in refractive index between the low refractive index film and the first protective film is 0.2 or less.

3. The light emitting device according to claim 1, wherein the low refractive index film is provided so as to cover an upper surface of the first protective film.

4. The light emitting device according to claim 1, further comprising
a second protective film stacked on the first protective film, wherein
the second protective film has a refractive index higher than the refractive index of the low refractive index film.

5. The light emitting device according to claim 4, wherein
the second protective film has a refractive index equivalent to or lower than the refractive index of the first protective film.

6. The light emitting device according to claim 4, wherein the second protective film covers the low refractive index film.

7. The light emitting device according to claim 6, wherein a part of the low refractive index film protruding from the first trench has a lens shape.

8. The light emitting device according to claim 4, wherein the second protective film is divided by a part of the low refractive index film protruding from the first trench.

9. The light emitting device according to claim 8, further comprising a color filter stacked on the second protective film.

10. The light emitting device according to claim 9, wherein the part of the low refractive index film protruding from the first trench is in contact with the color filter.

11. The light emitting device according to claim 9, wherein the part of the low refractive index film protruding from the first trench divides the color filter.

12. The light emitting device according to claim 9, wherein
the second protective film has a refractive index between the refractive index of the first protective film and a refractive index of the color filter.

13. The light emitting device according to claim 4, wherein the second protective film is embedded in a part of the first trench.

14. The light emitting device according to claim 1, wherein the first trench has a tapered shape expanding upward.

15. The light emitting device according to claim 1, wherein parts of the second electrodes of the adjacent light emitting elements are electrically connected to each other.

16. The light emitting device according to claim 4, wherein
each of the light emitting elements includes:
a contact hole provided in the first protective film to expose a part of an upper surface of the second electrode; and
first wiring to cover at least a part of a side surface of the contact hole, and
the first wiring is covered with the first protective film.

17. The light emitting device according to claim 16, wherein the low refractive index film is embedded in the contact hole.

18. The light emitting device according to claim 16, wherein the second protective film is embedded in the contact hole.

19. The light emitting device according to claim 1, wherein
each of the light emitting elements includes:
a contact hole provided in the first protective film to expose a part of an upper surface of the second electrode; and
second wiring covering at least a part of a side surface of the contact hole,
the second wiring is covered with the first protective film, and
a first color conversion film is embedded in at least a part of the contact hole in at least a part of the plurality of light emitting elements.

20. The light emitting device according to claim 19, wherein the light emitting element having the contact hole in which the first color conversion film is embedded and the light emitting element having the contact hole in which the first color conversion film is not embedded emit light of different colors.

21. The light emitting device according to claim 19, wherein the first color conversion film is at least embedded in at least a part of the contact holes of all the light emitting elements among the plurality of light emitting elements.

22. The light emitting device according to claim 19, wherein
the first color conversion film has a higher refractive index than the refractive index of the low refractive index film.

23. The light emitting device according to claim 19, wherein the first color conversion film is provided so as to fill the entire contact hole.

24. The light emitting device according to claim 23, wherein each of the light emitting elements further includes a second color conversion film stacked on the first color conversion film.

25. The light emitting device according to claim 24, wherein the second color conversion film is in contact with the low refractive index film embedded in the first trench.

26. The light emitting device according to claim 23, wherein
each of the light emitting elements further includes a third protective film stacked on the first color conversion film, and
the third protective film has a higher refractive index than the refractive index of the low refractive index film.

27. The light emitting device according to claim 26, wherein each of the light emitting elements further includes a third color conversion film stacked on the third protective film.

28. The light emitting device according to claim 19, wherein
a fourth protective film is embedded in a bottom portion of the contact hole, and
the first color conversion film is stacked on the fourth protective film.

29. The light emitting device according to claim 28, wherein the fourth protective film has a higher refractive index than the refractive index of the low refractive index film.

30. The light emitting device according to claim 19, wherein the first color conversion film is a color filter having a color of red, blue, or green.

31. The light emitting device according to claim 1, wherein
each of the light emitting elements further includes third wiring electrically connected to at least a part of an outer periphery of an upper surface of the second electrode, and
the second electrode is electrically connected to the second electrode of the adjacent light emitting element via the third wiring.

32. The light emitting device according to claim 31, wherein each of the light emitting elements further includes a sidewall portion covering a side surface of the first electrode and a side surface of the light emitting layer, and the third wiring extends onto the sidewall portion.

33. The light emitting device according to claim 32, wherein
the first protective film includes:
a fifth protective film stacked on the second electrode; and
a sixth protective film covering the fifth protective film and the sidewall portion,
the sixth protective films of the adjacent light emitting elements are provided so as to be continuous with each other, and
the third wiring extends onto an upper surface and a side surface of the fifth protective film.

34. The light emitting device according to claim 31, wherein the third wiring is electrically connected to a contact provided between the adjacent light emitting elements.

35. The light emitting device according to claim 34, further comprising
a second trench provided between the adjacent light emitting elements on the substrate, the second trench exposing an upper surface of the contact, wherein
the third wiring extends to at least a part of a side surface of the second trench.

36. The light emitting device according to claim 32, wherein
the sidewall portion is provided so as to be embedded between the adjacent light emitting elements.

37. The light emitting device according to claim 1, wherein the light emitting element has a polygonal shape, a circular shape, or an elliptical shape.

38. The light emitting device according to claim 1, wherein
the light emitting layer emits at least one of white light, red light, green light, or blue light.

39. An electronic device equipped with a light emitting device, the light emitting device including a plurality of light emitting elements arrayed on a substrate, wherein
each of the light emitting elements includes:
a first electrode provided on the substrate;
a light emitting layer stacked on the first electrode to emit light;
a second electrode stacked on the light emitting layer to transmit the light from the light emitting layer; and
a first protective film stacked on the second electrode to transmit the light from the light emitting layer,
the first protective films of the adjacent light emitting elements are provided to be continuous with each other,
the first protective film has a first trench that partitions the adjacent light emitting elements, and
a low refractive index film having a refractive index lower than a refractive index of the first protective film is embedded in the first trench.
